(19) United States
(12) Patent Application Publication
(10) Pub. No.: US 2026/0352975 A1
(43) Pub. Date: Nov. 5, 2026

(54) IMAGING DEVICE AND IMAGING SYSTEM

(71) Applicant: AMS-OSRAM International GmbH, Regensburg (DE)

(72) Inventors: Giacomo COLZI, Rüschlikon (CH); Pablo Jesús TRUJILLO SERRANO, Zurich (CH)

(21) Appl. No.: 19/488,598

(22) PCT Filed: Jul. 19, 2024
(86) PCT No.: PCT/EP2024/070560

§ 371 Date: Nov. 27, 2025

(30) Foreign Application Priority Data
Jul. 31, 2023 (DE) 10 2023 120 258.8

(51) Int. Cl. H04N 25/702; G06V 10/147; G06V 10/26; G06V 10/771; H04N 23/55; H04N 25/10

(52) U.S. Cl. CPC H04N 25/702; G06V 10/147; G06V 10/26; G06V 10/771; H04N 23/55; H04N 25/10

(57) ABSTRACT

The present disclosure relates to an imaging device including: an image sensor including an array of sensor pixels, wherein the array of sensor pixels has a first lateral dimension in a first direction and a second lateral dimension in a second direction orthogonal to the first direction, wherein the first lateral dimension is greater than the second lateral dimension; and imaging optics configured to collect light and project the collected light onto the array of sensor pixels, wherein the imaging optics is configured to project the collected light with a first magnification in the first direction and with a second magnification in the second direction, wherein the first magnification is greater than the second magnification, wherein a ratio of the second magnification to the first magnification is equal to a ratio of the second lateral dimension to the first lateral dimension.

### TECHNICAL FIELD

The present disclosure relates generally to an imaging device including an image sensor, and to an imaging system including a plurality of imaging devices.

### BACKGROUND

In general, imaging devices capable of capturing two-dimensional (2D) or three-dimensional (3D) information within a scene are of great importance for a variety of application scenarios, both in industrial- as well as in home-settings. A prominent example is the use of tracking sensors for augmented reality (AR) and virtual reality (VR) applications. For example, a world-tracking sensor allows sensing the environment around the user wearing the sensor, and further allows sensing where the user is heading (e.g., similar to head tracking). As another example, a gesture-tracking sensor allows sensing where the user's fingers and hands are, and in which form they are moving. As a further example, an eye-tracking sensor allows sensing where exactly the user is looking at and what the user is focusing on. Sensing data from the tracking sensors enable a variety of functionalities in the AR- and VR-context, such as presenting information to the user, executing commands based on a gesture or a gaze of the user, and the like. Other fields of application may include face recognition and authentication in modern smartphones, factory automation for Industry 5.0, authentication systems for electronic payments, internet-of-things (IoT) environments, and the like. Improvements in imaging devices may thus be of particular relevance for the further advancement of several technologies.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows an image sensor including an array of sensor pixels, in a schematic representation according to various aspects;

FIG. 2A and FIG. 2B show an imaging device including the image sensor, in a schematic representation according to various aspects;

FIG. 2C shows exemplary diagrams of a pattern collected via a full resolution camera and of a pattern collected via the imaging device, according to various aspects;

FIG. 2D shows exemplary implementations of the imaging device and of a corresponding collected pattern, according to various aspects;

FIG. 3A shows an imaging system including a plurality of imaging devices, in a schematic representation according to various aspects;

FIG. 3B shows a further configuration of the imaging system, in a schematic representation according to various aspects;

FIG. 3C shows a further configuration of the imaging system, in a schematic representation according to various aspects;

FIG. 4A to FIG. 4C show exemplary images collected via the imaging devices of the imaging system, according to various aspects; and

FIG. 5A and FIG. 5B show an integration of the imaging system in a host device, in a schematic representation according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects.

In general, cameras in consumer electronics and mobile devices allow 2D- and 3D-sensing to enable different applications, such as depth sensing, eye tracking, hand tracking, and the like. For example, tracking sensors for augmented reality and/or virtual reality may be camera-based visual sensors operating in the visible spectral bandwidth and/or near-infrared (NIR) spectral bandwidth, in view of the human sense of sight. An imaging device for such applications may usually include a compact camera module (CCM) for sensing light and generating corresponding image data (also referred to herein as sensing data). For example, such imaging device may include a RGB camera configured to deliver colored images by sensing light at or around red, green, and blue wavelengths, or a NIR camera. With the advancements of new generations of imaging devices, there is a constant demand for a miniaturization of their mechanical, optical, and electrical components.

Various application-driven requirements are usually considered as desirables, or targets to be reached, when designing a camera-based sensor. These design requirements may include: a small size, especially a small footprint; a high frame rate, e.g. in the order of hundreds of Hertz, for example to allow a smooth tracking of eye movement and gestures of a user; a sensing robustness, e.g. a high signal-to-noise ratio (SNR) and/or a low latency; capabilities of operating in indoor and outdoor environments; a low power consumption; and a low cost of the materials. The consumer market favors small footprint solutions that are easy to integrate in the full system, and typically lead to a better user experience and more freedom to design. One of such examples is the screen-to-body ratio maximization by means of the notch reduction in phone displays.

In general, reducing the footprint of a sensor may come with the compromise of a reduced optical performance. Illustratively, image sensors with a reduced footprint may have pixels with smaller size compared to larger sensors, and such relatively small pixels may capture less light, may have less dynamic range and shorter depth of field, and in general may deliver a lower image quality. A larger pupil typically translates in a higher signal to noise ratio, less challenges in the design to ensure a high field of view, and in a better diffraction-limited performance. Regarding the image sensor, a smaller footprint may translate into less pixels and, accordingly, a lower resolution. The allowed camera footprint dictates thus a limit to the camera optical performance. Generally speaking, the resolution of the camera system may be limited by the combination of optics quality and sensor resolution.

However, image sensors with a relatively small footprint are of particular relevance for applications in portable and mobile devices, to allow integration of imaging functionalities in compact environments while reducing the visual impact for the users. For example, an emerging trend is the development of lightweight, comfortable, and discrete wearables (e.g., glasses, watches, headbands, etc.). In this context, small footprint camera-based sensors may be disposed in the tight and narrow spaces available in such type of devices. As an example, a camera-based sensor may be integrated in the corners of a display area, e.g. in the corners of a frame surrounding the display area (for example in a smartphone, or a smartwatch). As another example, a camera-based sensor may be integrated in the corners of a frame of a pair of glasses, e.g. smart glasses. An additional example related to future trends may include thin frame AR-glasses with sensors and cameras fully incorporated into a casual-looking frame. In this context, “stripe-shaped” cameras may be provided, which may fit in such tight spaces. Stripe-shaped cameras may fit on thin frames (e.g., glasses) or on the corners of displays to reduce the visual impact, however such type of camera and sensor design would likely lead to poor performance unless some counter-measures are adopted.

The present application may be based on the realization that a “stripe-shaped” camera (illustratively, an imaging device with a rectangular image sensor) may on the one hand pose challenges in terms of optical performances but, on the other hand, may possess structural properties that may be exploited to enable a simple, yet accurate, feature extraction to gather information from a scene. Illustratively, the present application may be based on the realization that the (high) aspect ratio of a “stripe-shaped” camera may be advantageously integrated in various types of modern devices and further represents an opportunity to enable an accurate detection of certain types of features in the scene.

The strategy proposed herein may be based on imaging a scene via an imaging device with a stripe-shaped image sensor, in which imaging optics is adapted to project light onto the sensor with different resolutions along the two symmetry axes of the sensor (e.g., different resolutions in the horizontal direction and vertical direction, as an example). The imaging optics may be adapted to define different magnification factors in the two directions corresponding to the two symmetry axes of the image sensor (and in some aspects, an equal angular field of view along the two directions). Contrary to conventional systems, the proposed imaging optics does not lead to a reduced field of view for the image sensor, but is rather configured to project onto the image sensor the same angle of subject's area for the two directions corresponding to the symmetry axes.

Aspects of the present disclosure are based on the realization that such configuration allows imaging the scene via the image sensor with a reduced resolution along one axis (the axis corresponding to the shorter dimension of the rectangular array) and a higher resolution along the other axis (the axis corresponding to the longer dimension of the rectangular array). The relatively high(er) resolution along one of the axes may be exploited to accurately image features in the scene that have an orientation compatible with that axis. Illustratively, as the camera has a high resolution axis, spatial frequencies along that axis are sampled with a higher resolution. The imaging device configured as described herein may thus allow reliably extracting features to obtain information about a scene, while maintaining an overall geometry that is suitable for integration in portable/mobile/wearable devices.

According to various aspects, an imaging device may include: an image sensor including an array of sensor pixels, wherein the array of sensor pixels has a first lateral dimension in a first direction and second lateral dimension in a second direction perpendicular to the first direction, wherein the first lateral dimension is greater than the second lateral dimension; and imaging optics configured to collect light and project the collected light onto the array of sensor pixels, wherein the imaging optics is configured to project the collected light onto the array of sensor pixels with a first magnification in the first direction and with a second magnification in the second direction, wherein the first magnification is greater than the second magnification.

According to various aspects, an imaging device may include: an image sensor including an array of sensor pixels, wherein the array of sensor pixels has a first lateral dimension in a first direction and second lateral dimension in a second direction perpendicular to the first direction, wherein the first lateral dimension is greater than the second lateral dimension; and imaging optics configured to collect light and project the collected light onto the array of sensor pixels, wherein the imaging optics is configured to define a first effective focal length for the first direction and a second effective focal length for the second direction, wherein the first effective focal length is greater than the second effective focal length.

As mentioned earlier, the resolution of the full system on the image plane is impacted both by the quality of the optics, (e.g., which can be quantified by the point spread function (PSF), or by its spatial frequency response) and by the sensor resolution (e.g., which may be quantified by the pixel pitch of the sensor, or equivalently its Nyquist frequency). A combination of these two quantities defines the resolution of the image on the image sensor itself, with the best attainable performance limited by the worst of the two. The imaging optics also define a magnification, which may also be referred to herein as system magnification, or optical system magnification.

In the context of the present disclosure, a property of particular interest may be the object space resolution, which is a parameter that relates to both image space resolution and system magnification. Such a property quantifies the minimum feature size (also in angular units) that can be recognized on the object, or equivalently the highest spatial frequency that can be resolved. As an illustrative example of this, for a high-quality optical system, whose PSF is negligible compared to the sensor pixel size, imaging an object located at finite distance on a sensor whose image space resolution is determined by a pixel size of 10 micrometers, will allow to barely resolve features of 20 micrometers size on the object if the magnification is ×1 (where the factor of 2 accounts for the sampling of the feature). However, if the magnification factor is ×0.25 (i.e., the image projected on the sensor is 4 times smaller compared to the real object), the sensor's intrinsic resolution remains the same, but the smallest feature that can be resolved on the real object is increased to 80 micrometers. The same conclusion holds when the image space resolution is limited by the optics PSF, and when the magnification factor is defined in relation to the angular size of the object features.

The term “magnification” describes the scale factor between the size of the object being imaged and the corresponding image on the sensor plane. As a preferred configuration of the imaging device proposed herein, the imaging optics may be configured such that for a planar object located at a distance Z much larger than the optical system's EFL the image will form (ideally) on a plane located at the back focal distance (BFD) from the last element. In fact, representing the situation in ray optics, the rays reaching the system's optical aperture from any point of the far away object will be (substantially) parallel to each other. The system is assumed, only for this illustrative example, to be radially symmetric. The relationship between an image point on the object plane (distanced R from the z-axis) and the corresponding distance r′ from the sensor principal point will be given by the relationship:

$${r}^{′} = E F L * \frac{R}{Z} = E F L * tan ( θ )$$

where, for a far object, the effective focal length (EFL) defines a proportionality relationship between the angular coordinates' tangent of the far away object, and the positions at which the corresponding features are imaged. This is also exemplary of imaging systems that define a different relationship between the angular coordinates of the object, and the sensor image point, for example f-theta lenses, where the relationship is a direct proportionality. Analogously, when the distance Z is known, the EFL/Z ratio establishes the proportionality between the coordinates R (in length units) of the coordinates of the sensor where the image of such features is formed. In either case, a shorter focal length will result in a smaller sensor image. According to various aspects, the term “magnification” may describe the ratio between the size of the object image on the sensor and the tangent of the angle subtended by the object. Practically, this ratio coincides with the EFL itself. This hybrid definition is convenient in the context of this disclosure, and the conclusions discussed can be readily reformulated in terms of canonical linear or angular magnification factors where needed. The linear magnification, defined as the ratio between the size of the object image on the sensor and the size of the real object, may be instead preferred when dealing with cameras optimized for producing an image of an object located at a finite distance, such as cameras including macro-lenses.

According to various aspects, the imaging optics (also referred to as optical system) may be configured to define two different EFL values for the two x- and y-directions, where z is the optical axis direction, and the same back focal distance. This leads to an image forming on the same plane (illustratively, on the image sensor) with two different magnification factors along two orthogonal directions—illustratively an object of square proportions will be imaged on a rectangle (neglecting distortion effects), and the proportion of such rectangle defines an image aspect ratio. In virtue of the above description, the sensor and optical resolution defined on the image plane will return a differently scaled object space resolution, with a better scaling in the larger sensor direction, corresponding to a larger magnification.

Further aspects of the present disclosure are related to an imaging system including a plurality of the imaging devices. In the proposed imaging system, each “stripe-shaped” imaging device may have its longer dimension (the length of the rectangular array) oriented along a respective orientation direction, so that different imaging devices may enable a high-resolution imaging of different types of features in the scene (illustratively, features that have an orientation compatible with the respective orientation of the imaging device). For example, the image data from different imaging devices may be combined to reconstruct the scene, or to recognize a particular object in the scene, or some features of interest (e.g., the hands of a user, the eyes of a user, and the like). Illustratively, the information that may be partially lost when using a single imaging device (due to the lower resolution along one axis) may be integrated with the information from the other imaging devices, thus enabling a more detailed characterization of the scene. Several cameras rotated at different angles will sample different directions with more precision compared to a single miniaturized camera.

The proposed solution allows to use two or more cameras of high aspect ratio, with parallel optical axes and the bases rotated at different angles. For instance, two rectangular cameras may be rotated around the optical axis by 90° with respect to each other. The cameras are fully integrated in a system and exploit its design features (e.g., support frame of glasses) minimizing the visual impact compared to a single full resolution camera. Combining the images of the different cameras (e.g., with the help of a suitable software) allows to mitigate the performance limitation of the individual camera. Each individual camera shows a reduced footprint allowing integration in challenging designs (e.g., the frame of glasses). The drop in performance caused by the reduced resolution of the camera on the short axis may be in part counterbalanced by the other cameras that are mounted in the system and provide additional information on the scene.

The approach proposed herein may have relevant applications in scenarios where an overall high resolution may not be needed for the desired function to be implemented. This may be the case, for example, for tracking applications, in which a high resolution for the detection of the features to be tracked is not necessary to follow the evolution of the spatial coordinates of the features. As another example, applications based on feature recognition (e.g., face authentication in a smartphone) may function without a high resolution for the detection of the features, as they are rather based on recognizing patterns and (spatial) interrelationships among the features. As a further example, depth sensing based on time-of-flight may function even with a relatively low resolution for the light detection. Thus, in the present disclosure some aspects may be described with terminology that pertains to the context of tracking applications, time-of-flight sensing, or feature recognition applications.

Furthermore, the imaging devices proposed herein may be particularly suitable for integration in host devices that have a limited space available for hosting imaging functionalities, for example host devices in which the possible regions to integrate the imaging device may have a narrow geometry (e.g., a geometry elongated in one direction). For example, some aspects may be described in relation to the integration of the proposed imaging devices in border regions of a device (e.g., the frame of a pair of glasses, the frame surrounding a display area, etc.).

It is however understood that the imaging device and imaging system described herein may in principle be applicable in any suitable end application and in any suitable host device. In general, the imaging device and imaging system described herein may be integrated in any suitable host device in which the stripe-shaped configuration of the imaging device(s) may be advantageous for integration in the geometry of the host device. Furthermore, the imaging device and imaging system described herein may be applicable for any end application in which an overall lower resolution (compared to a full resolution camera) may be acceptable to implement the desired function. Possible applications of this kind may include 3D ranging systems, such as direct or indirect time-of-flight cameras. Such kind of sensors are generally based on active illumination, and can offer more optical design flexibility compared to RGB cameras, where both achromatic and chromatic aberrations should be accounted for. The 3D information produced by different types of such sensors can be integrated, increasing the number of available cloud map points, and potentially be used in further integrations, such as SLAM (Simultaneous Localization and Mapping).

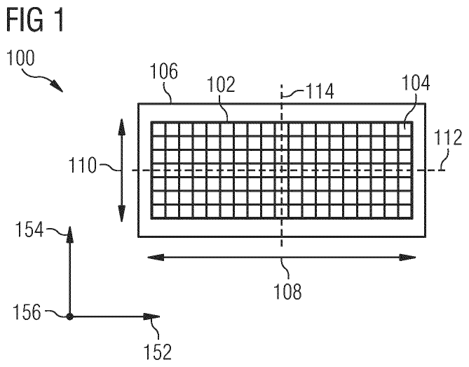

FIG. 1 shows an image sensor 100 in a schematic representation, according to various aspects. The general properties and functionalities of an image sensor (and sensor pixels) may be known in the art (e.g., possible configurations to convert light into a signal that may be further processed). A brief description of some general concepts is provided herein, to illustrate aspects relevant for the present disclosure.

In general, the image sensor 100 may include a plurality of sensor pixels 104 configured to detect light. Illustratively, a sensor pixel 104 may be a light-sensitive area configured to be sensitive for light in a certain wavelength range. A sensor pixel 104 may thus include any suitable circuitry and components to allow detecting light that impinges onto the sensor pixel 104. A sensor pixel 104 may thus be configured to receive light and generate a corresponding signal (also referred to herein as detection signal) representative of the received light. According to various aspects, a sensor pixel 104 may be or include an optoelectronic circuit configured to convert the received light into a corresponding electrical signal (e.g., a current, or a voltage). As an exemplary configuration, a sensor pixel 104 may be configured to generate an electrical current representative of the received light, and the sensor pixel 104 may include a transimpedance amplifier configured to convert the generated current into a corresponding (amplified) voltage. The detection signal generated by a sensor pixel 104 may represent various properties of the received light, such as an intensity, a color (depending on the wavelength according to which the sensor pixel 104 is configured), a time of arrival, a phase, and the like.

As an example, the image sensor 100 may be configured according to Complementary-Metal-Oxide-Semiconductor (CMOS) technology, e.g. the image sensor 100 may be a CMOS image sensor. In this configuration, a sensor pixel 104 may be a CMOS-pixel including a photodetector (e.g., a photodetector configured to be sensitive for light in the desired wavelength range) that accumulates an electrical charge based on the amount of light impinging onto the photodetector. As another exemplary configuration, the image sensor 100 may be configured according to Charged Coupled Device (CCD) technology, e.g. the image sensor 100 may be a CCD image sensor. In this configuration, a sensor pixel 104 may be a CCD-pixel with a photoactive region and a transmission region. It is understood that in principle a sensor pixel 104 may have any suitable configuration to enable light detection. A sensor pixel 104 may thus include a photosensitive element configured to convert light energy into an electrical signal (e.g., an electrical current). For example, a sensor pixel 104 (e.g., each sensor pixel) may include a photodiode. As examples, a sensor pixel 104 (e.g., each sensor pixel) may include at least one of a PIN photo diode, an avalanche photo diode (APD), a single photon avalanche diode, or a silicon photomultiplier.

In general, a sensor pixel 104 may be configured to detect light in any suitable wavelength range of interest. As an example, a sensor pixel 104 (e.g., each sensor pixel 104) may be configured to be sensitive for light in the visible wavelength range (illustratively, the visible spectrum considering the human's eye). Illustratively, a sensor pixel 104 may be configured to detect light with wavelength in the visible wavelength range, and generate a corresponding detection signal when light with such wavelength impinges onto the sensor pixel 104. As another example, a sensor pixel 104 (e.g., each sensor pixel 104) may be configured to be sensitive for light with wavelength outside the visible range (e.g., infrared light, or ultraviolet light), illustratively invisible radiation.

As a numerical example, a sensor pixel 104 may be configured to be sensitive for light with wavelength in the range from about 380 nm to about 700 nm. As another numerical example, a sensor pixel 104 may be configured to be sensitive for light with wavelength in the range from about 700 nm to about 5000 nm, for example in the range from about 860 nm to about 1600 nm. As a further numerical example, a sensor pixel 104 may be configured to be sensitive for light with wavelength in the range from about 100 nm to about 400 nm.

In a simple configuration, all the sensor pixels 104 may be configured to detect light in the same wavelength range. In another configuration, which provides a more complex but more versatile light detection, different sensor pixels 104 may be configured to be sensitive for light in different wavelength ranges, e.g. non-overlapping wavelength ranges. For example, this configuration may provide tailoring the light detection capabilities of the image sensor 100 to an expected emission pattern of emitted light in a detection system, e.g. to receive and detect in different portions of the sensor 100 light coming from different light sources and having different wavelengths. As another example, this configuration may provide optimizing the individual sensor pixels 104 for specific wavelengths (e.g., red, green, blue) to enhance the light detection at the wavelengths of interest.

According to various aspects, a (first) sensor pixel 104 (or a first subset of sensor pixels 104) may be configured to be sensitive for light in a first wavelength range, and another (second) sensor pixel 104 (or a second subset of sensor pixels 104) may be configured to be sensitive for light in a second wavelength range different from the first wavelength range. For example, a further (third) sensor pixel 104 (or a third subset of sensor pixels 104) may be configured to be sensitive for light in a third wavelength range different from the first and second wavelength ranges, etc. A “subset” of sensor pixels 104 may include a more than one sensor pixel 104 but less than a total number of sensor pixels 104. In general, the different wavelength ranges may be non-overlapping with one another, so that the wavelengths contained in each wavelength range are unique to that wavelength range and are not part of the other wavelength ranges. For example, in some aspects, the image sensor 100 may be configured for RGB detection, e.g. as part of a RGB camera.

A wavelength range may be centered around a wavelength of interest. For example, the first wavelength range may be centered around a first wavelength (e.g., red, e.g. around 700 nm), the second wavelength range may be centered around a second wavelength (e.g., green, e.g. around 515 nm), the third wavelength range may be centered around a third wavelength (e.g., blue, e.g. around 470 nm), etc. The width of a wavelength range may be adapted depending on desired properties for the light detection, e.g. in terms of selectivity (for which narrower ranges may be provided), amount of signal (for which broader ranges may be provided), and the like. As a numerical example, a wavelength range may have a bandwidth in the range from 20 nm to 200 nm, for example in the range from 30 nm to 60 nm.

In some aspects (not shown), the image sensor 100 may include one or more spectral filters configured to filter light, e.g. configured to block light with wavelength outside a predefined wavelength range. A spectral filter may thus enhance the signal-to-noise ratio of imaging carried out using the image sensor 100. A spectral filter may be configured to filter light in any suitable wavelength range according to the desired application of the image sensor 100 (and according to the corresponding configuration of the sensor pixels 104). As an example, the spectral filter may be configured to block light with wavelength outside of the visible range. As another example, the spectral filter may be configured to block light with wavelength outside of the infrared wavelength range, or outside of the ultraviolet wavelength range.

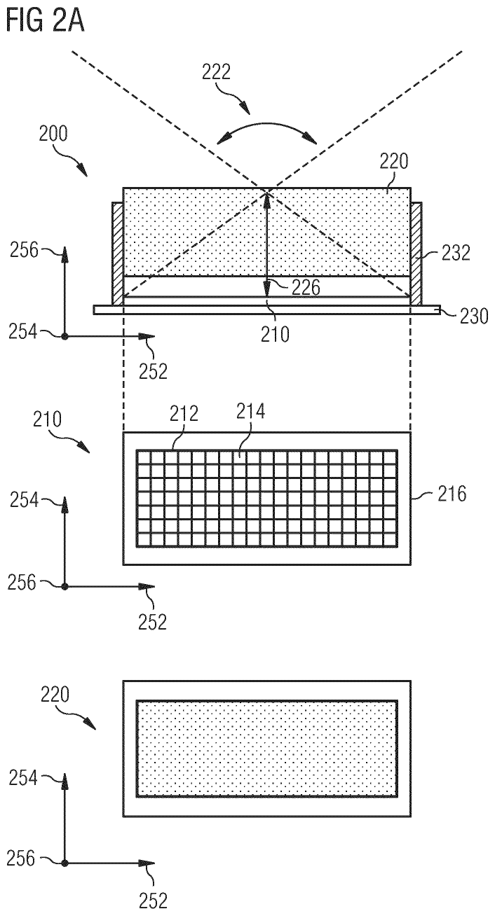

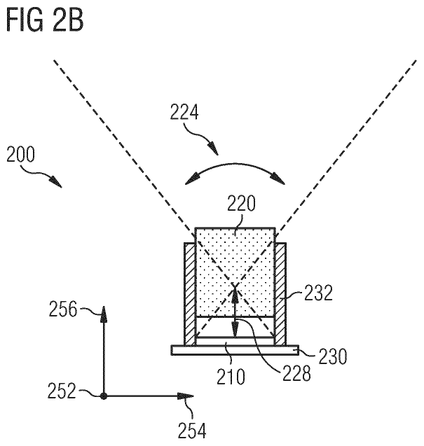

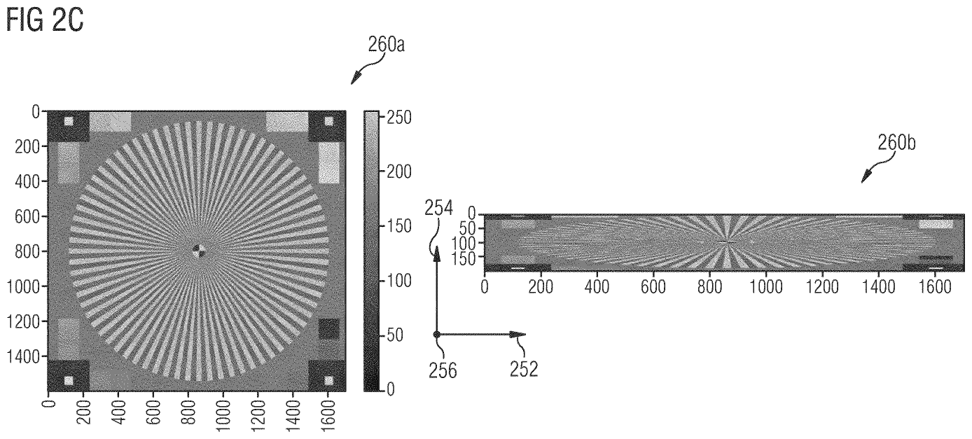

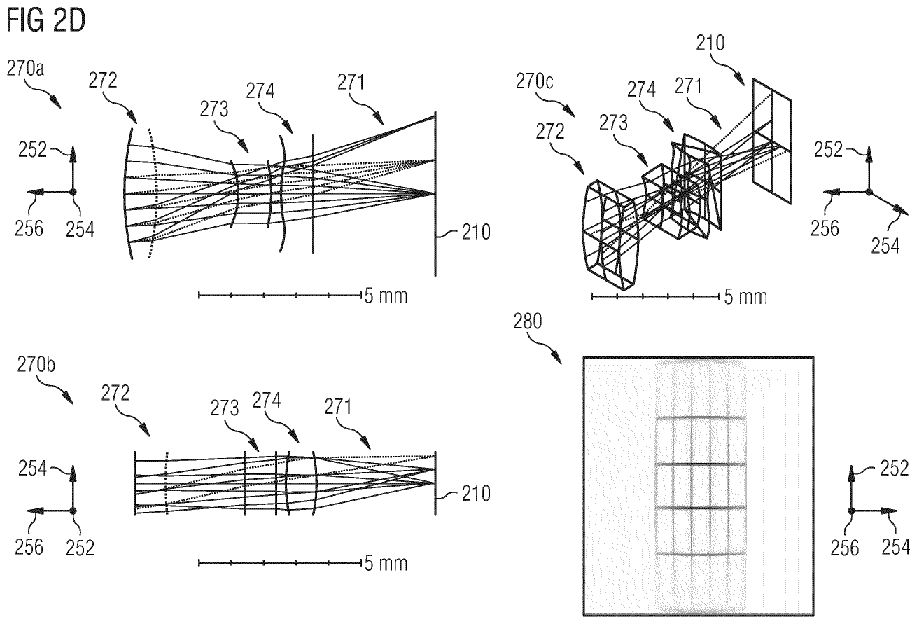

According to various aspects, the image sensor 100 may be further configured to deliver time information associated with the light detection. In this regard, some aspects of the present disclosure may be based on the realization that the proposed configuration (see also FIG. 2A to FIG. 4C) may be conveniently applied to depth measurements, e.g. distance measurements based on time-of-flight (e.g. direct time-of-flight or indirect time-of-flight), which are a type of applications for which a relatively low resolution may suffice for the detection process.

In an exemplary configuration, a sensor pixel 104 (e.g., each sensor pixel) may be configured to deliver timestamp information representative of an arrival time of light (e.g., a photon) onto the sensor pixel 104. Illustratively, a sensor pixel 104 may be configured to generate a detection signal representative of a time of arrival of light at the sensor pixel 104. For example, a sensor pixel 104 may include a time-to-digital converter configured to generate a digital signal in response to the event of light impinging onto the sensor pixel 104. This configuration may be provided, for example, for direct time-of-flight applications in which a depth measurement in the scene is carried out based on the length of the optical round trip “illuminator-to-sensor”. In such configuration a sensor pixel 104 may thus be configured to acquire time-resolved events.

As another exemplary configuration, a sensor pixel 104 (e.g., each sensor pixel) may be configured generate a detection signal representative of a phase of the received light. For example, a sensor pixel 104 may include a phase detector configured to detect the phase of the electrical signal generated by the photosensitive element of the sensor pixel 104. This configuration may be provided, for example, for indirect time-of-flight applications in which a depth measurement in the scene is carried out based on the phase difference between the emitted light (or emitted light pattern) and received light (or received light pattern).

The strategy proposed herein may be implemented with an image sensor 100 with a relatively high aspect ratio, as discussed in further detail below. In this connection, the sensor pixels 104 may be disposed in a two-dimensional array 102, e.g. a rectangular array 102 of sensor pixels 104. In general, the array 102 of sensor pixels 104 may include a first plurality of pixels Nₓ defining a first lateral dimension 108, and a second plurality of pixels N_{y} defining a second lateral dimension 110. Illustratively, the array 102 of sensor pixels 104 may include a first number of sensor pixels 104 in a first direction 152, and a second number of sensor pixels 104 in a second direction 154 (perpendicular to the first direction 152). The high aspect ratio may enable integration of the image sensor 100 in narrow spaces, and the corresponding optics may be adapted to enable a relatively high resolution along one of the axes, as discussed in further detail in relation to FIG. 2A to FIG. 2D.

In the exemplary configuration in FIG. 1, the image sensor 100 may have a greater number of sensor pixels 104 in the first direction 152 (e.g., the horizontal direction) compared to the second direction 154 (e.g., the vertical direction). In the exemplary configuration in FIG. 1, the image sensor 100 may thus have a first lateral dimension 108 in the first direction 152 greater than a second lateral dimension 110 in the second direction 154. In this regard, the main lateral dimension of the array 102 (e.g., the first lateral dimension 108) may be referred to as length of the array 102, and the other (secondary) lateral dimension of the array (e.g., the second lateral dimension 110) may be referred to as width of the array 102. As another definition, the main lateral dimension of the array 102 may be referred to as width of the array 102, and the secondary lateral dimension may be referred to as height of the array 102. It is however understood that the definitions of horizontal direction, vertical direction, width, length, height, etc. may be arbitrary, e.g. depending on the standpoint from which the image sensor 100 is viewed. In general, a plane defined by the first direction 152 and second direction 154 may be perpendicular to a third direction 156, which may be a direction parallel to an optical axis of an imaging device including the image sensor 100 (see also FIG. 2A and FIG. 2B). Without loss of generality, the first direction 152 may be referred to as x-direction, the second direction 154 may be referred to as y-direction, and the third direction 156 may be referred to as z-direction.

The main dimension (also referred to as major dimension) of the array 102 may be along a first axis 112, and the other dimension of the array 102 may be along a second axis 114. The first axis 112 may be a main axis (also referred to as major axis, primary axis, or long axis) of the rectangular array 102, e.g. the first axis 112 may be a first axis of symmetry of the rectangular array. The second axis 114 may be a minor axis (also referred to as secondary axis or short axis) of the rectangular array 102, e.g. the second axis 114 may be a second axis of symmetry of the rectangular array. Illustratively, the first axis 112 and the second axis 114 may be a major axis and a minor axis of the rectangular footprint of the image sensor 100.

In principle, the number of sensor pixels 104 Nₓ, N_{y} in each direction 152, 154 (and accordingly the aspect ratio of the array 102) may be adapted depending on the end application of the image sensor 100, e.g. depending on geometrical/structural considerations regarding the host device. The imaging strategy proposed herein (see FIG. 2A to FIG. 2C) may be suitable to operate with arrays of sensor pixels 104 with more “pushed” aspect ratios compared to conventional configurations, thus making it more flexible for integration in more confined spaces. In this regard, the term “aspect ratio” may be used herein in relation to the array 102 of sensor pixels 104 to describe a ratio of the minor dimension of the array 102 (e.g., expressed in millimeters, or number of sensor pixels 104) to the main (major) dimension of the array 102. For example, the term “aspect ratio” may describe a ratio of the second number of sensor pixels 104 in the second direction 154 to the first number of sensor pixels 104 in the first direction 152 (N_{y}:Nₓ). As another example, the term “aspect ratio” may describe a ratio of the lateral dimension of the array 102 in the second direction 154 to the lateral dimension of the array 102 in the first direction 152 (e.g., height:width, or width:length).

In general, conventional configurations for an image sensor may have an aspect ratio of 4:3 as a well established value. In addition to such conventional geometry, the strategy proposed herein may be applicable to rectangular arrays 102 with a larger difference between the two dimensions, thus allowing to further exploit the relatively higher resolution of the imaging along one of the axes while providing a “stripe” shape that allows integration in narrow spaces (e.g., in a frame), as discussed in further detail below. As an example, an aspect ratio of the array 102 may be in the range from 1:2 to 1:10. As an example, an aspect ratio of the array 102 may be at least 1:4, for example the aspect ratio of the array 102 may be 1:8.

Illustratively, according to various aspects, the number of sensor pixels 104 along the main dimension (e.g., the first number of sensor pixels 104 in the first direction 152) may be at least two times greater than the number of sensor pixels 104 along the secondary dimension (e.g., the second number of sensor pixels 104 in the second direction 154). For example, the number of sensor pixels 104 along the main dimension may be at least four times greater than the number of sensor pixels 104 along the secondary dimension, for example at least eight times greater, for example at least ten times greater. Stated differently, according to various aspects, the main dimension of the array 102 (the dimension along the main axis, e.g. the first lateral dimension 108 along the first axis 112) may be at least two times greater than the secondary dimension of the array 102 (the dimension along the minor axis, e.g. the second lateral dimension 110 along the second axis 114). For example, the main dimension of the array 102 may be at least four times greater than the secondary dimension of the array 102, for example at least eight times greater, for example at least ten times greater.

Such aspect ratios have been found suitable for some relevant applications of the proposed strategy (e.g., for integration in the corners of a display area). It is however understood that the geometry of the array 102 is not limited to the aspect ratios mentioned above, and in principle the array 102 may be adapted to any suitable aspect ratio.

The number of sensor pixels 104 in each direction, and accordingly the lateral dimensions of the array 102, may be adapted depending on the desired aspect ratio and on a desired end geometry for the image sensor 100. As a numerical example, the number of sensor pixels 104 along the main dimension (e.g., the first number of sensor pixels 104 in the first direction 152) may be in the range from 200 to 5000, for example in the range from 100 to 1000. As another numerical example, the number of sensor pixels 104 along the secondary dimension (e.g., the second number of sensor pixels 104 in the second direction 154) may be in the range from 20 to 500, for example in the range from 10 to 100. As a further numerical example, the array 102 of sensor pixels 104 may have a main (first) lateral dimension 108 in the range from 1 mm to 50 mm, for example in the range from 2 mm to 10 mm, for example in the range from 3 mm to 5 mm. As another numerical example, the array 102 of sensor pixels 104 may have a secondary (second) lateral dimension 110 in the range from 0.1 mm to 5 mm, for example in the range from 0.2 mm to 1 mm, for example in the range from 0.3 mm to 0.5 mm.

Such exemplary values have been found suitable for some relevant applications of the proposed strategy (e.g., for integration in portable/mobile/wearable devices). It is however understood that the size of the array 102 is not limited to the values mentioned above, and in principle the array 102 may be adapted to any suitable dimension.

It is also understood that the aspects described herein may apply in a corresponding manner to a configuration for which the aspect ratio of the array 102 in pixel units does not match the aspect ratio of the array 102 in length units. Illustratively, in various aspects the sensor pixels 104 may have a square shape (and thus the same dimension in the two directions 152, 154), so that the aspect ratio of the array 102 in pixel units matches the aspect ratio of the array 102 in length units. However, in principle the sensor pixels 104 may also have a different shape, e.g. a rectangular shape. In this scenario, a sensor pixel 104 may have different dimensions in the two directions 152, 154, so that there may be a difference in the aspect ratio expressed based on the number of pixels and the aspect ratio expressed based on the lateral dimensions. In such cases, the physical size of the sensor determines the relevant sensor aspect ratio, relating directly to the attainable module footprint, while the underlying pixel structure may have a quantitative effect on the sensor resolution. As an example, the effect of such arrangement may be negligible if both pixel dimensions are significantly smaller than the PSF of the imaging optics, or may reduce/increase the sensor resolution in a given direction otherwise, compared to square pixels, while the aspect ratio remains the one defined by the sensor physical size. The aspects described herein may refer implicitly to the case of a square pixel arrangement for illustrative simplicity, but may apply in a corresponding manner to other pixel arrangements (e.g., including rectangular pixels).

According to various aspects, as shown in FIG. 1, the image sensor 100 may include a substrate 106, and the sensor pixels 104 may be disposed (e.g., formed) on the substrate 106. The substrate 106 may be configured to enable electrical connections among the sensor pixels 104, and to enable electrical connections between the sensor pixels 104 and other circuits external to the image sensor 100 (e.g., a processing circuit, or other circuits of a host device, as examples). The substrate 106 may thus include electrical wirings, contact pads, and the like, to provide electrical connections according to a desired circuit design. As an example, the substrate 106 may be a printed circuit board (PCB). In some aspects, the substrate 106 may include further circuits integrated on the substrate 106 to implement various functionalities for the image sensor 100, e.g. a clock generator, one or more switches, and the like. The substrate 106 may be a rigid substrate or a flexible substrate, depending on the intended use case for the image sensor 100. The substrate 106 may have the same aspect ratio as the array 102 of sensor pixels 104, or may have a different geometry (e.g., with a different aspect ratio, or with a different shape, such as square, circular, elliptical, etc.) depending on considerations regarding the host device in which the image sensor 100 should be integrated.

According to the strategy proposed herein, an image sensor with a (high) aspect ratio may be exploited to enable feature extraction from a scene, or other types of detection/sensing applications (e.g., depth measurements), by projecting light onto the sensor in a way that achieves different resolutions in the two directions corresponding to the two axes of the array of sensor pixels. As outlined previously, while the image resolution on the sensor plane may be isotropic in the two x- and y-direction (given for example a combination of square pixels and a perfectly circular optical PSF), the corresponding resolution in the object plane will be different in virtue of the different magnification values in the two directions—or equivalently, an image aspect ratio matching the sensor aspect ratio. The proposed configuration will be described in further detail in relation to FIG. 2A to FIG. 2D.

FIG. 2A and FIG. 2B show an imaging device 200 in a schematic representation, according to various aspects. The imaging device 200 may include an image sensor 210. The image sensor 210 may be configured as the image sensor 100 described in FIG. 1, and may include an array 212 of sensor pixels 214 disposed on a substrate 216. The array 212 of sensor pixels 214 may include a first number of sensor pixels 214 in a first direction 252 and a second number of sensor pixels 214 in a second direction 254. In the exemplary configuration in FIG. 2A and FIG. 2B the main dimension of the array 212 may be along the first direction 252, which may thus correspond to a main axis of the array 212, and the first number of sensor pixels 214 may thus be greater than the second number of sensor pixels 214. In a corresponding manner, the first lateral dimension of the array 212 along the first direction 252 may be the main dimension, and may be greater than the second lateral dimension of the array 212 along the second direction 254. The array 212 (and correspondingly the image sensor 210) may thus have an aspect ratio that defines an elongated shape (e.g., a stripe shape) in the first direction 252. The imaging device 200 may also be referred to herein as camera, or camera device.

The first direction 252 may be perpendicular to the second direction 254, and the plane defined by the first (x-)direction 252 and the second (y-)direction 254 may be perpendicular to a third (z-)direction 256. The optical axis of the imaging device 200 may be along the third direction 256 (e.g., the optical axis may be aligned with the third direction 256). FIG. 2A shows a first side view of the imaging device 200, illustratively an Y-view as seen along the second direction 254. FIG. 2B shows a second side view of the imaging device 200, illustratively an X-view as seen along the first direction 252. Furthermore, FIG. 2A also shows a top view of the image sensor 210 and a top view of the imaging optics 220.

According to various aspects, in addition to the image sensor 210, the imaging device 200 may include imaging optics 220 configured to collect light and project the collected light onto the image sensor 210 (illustratively, onto the array 212 of sensor pixels 214). Illustratively, the imaging optics 220 may be an optical arrangement configured to collect light and direct (e.g., focus) the collected light for imaging via the image sensor 210. The imaging optics 220 may also be referred to herein as imaging system, optical system, optical module, or optical arrangement.

In some aspects, the imaging optics 220 may be configured to define the same angular field of view in the two directions parallel to the axes of the array 212 of sensor pixels 214. In general, the imaging optics 220 may be configured to define a first angular field of view in the first direction 252 (e.g., along the main dimension of the array 212) and a second angular field of view in the second direction 254 (e.g., along the secondary dimension of the array 212). By way of illustration, the imaging optics 220 may be configured to collect light with a first angular extension 222 in the first direction 252 for the first (major) array dimension, and with a second angular extension 224 in the second direction 254 for the second (minor) array dimension. The first angular field of view may be the angular extension of the region from which light is collected in a direction parallel to the first direction 252 (e.g., parallel to the main dimension of the array 212). In a corresponding manner, the second angular field of view may be the angular extension of the region from which light is collected in a direction parallel to the second direction 254 (e.g., parallel to the secondary dimension of the array 212). The (first and second) angular field of view may also be referred to herein as (first and second) angle of view.

In some aspects, the first angular field of view and the second angular field may have the same angular extension. Illustratively, in some aspects the imaging optics 220 may be configured to define the same angular field of view in the two directions parallel to the axes of the array 212 of sensor pixels 214. By way of illustration, in such configuration the imaging optics 220 may be configured to define a viewing cone symmetric around the optical axis of the imaging device 200. In a corresponding manner, the imaging optics 220 may be configured to define the same field of view for the array 212 of sensor pixels 214 along the first direction 252 and the second direction 254. Illustratively, in this configuration, the imaging optics 220 may be configured to define a first field of view with a first dimension along the first direction 252 and a second field of view with a second dimension along the second direction 254, and the first dimension may be equal to the second dimension. Angular field of view with the same angular extension in the two directions may allow filling the image sensor with the collected light in the two directions (in combination with the different magnification in the two directions). In other aspects, the first angular field of view and the second angular field may have (slightly) different angular extensions, as discussed in further detail below.

The first angular extension 222 may be the angle between the light captured at the edges of the imaging device 200 in the plane defined by the third direction 256 (and, accordingly, the optical axis) and the first direction 252. The second angular extension 224 may be the angle between the light captured at the edges of the imaging device 200 in the plane defined by the third direction 256 and the second direction 254. For a certain orientation of the imaging device, the first angular extension 222 may be the angle between the left edge of the viewable area and the right edge of the viewable area, and the second angular extension 222 may be the angle between the top edge of the viewable area and the bottom edge of the viewable area. In some aspects, the imaging optics 220 may be configured to project onto the array 212 of sensor pixels 214 the same angle of the viewable area along both axes of the array 212. The first/second angular extensions 222, 224 of the first/second angular field may be adapted according to the intended end application of the imaging device. As a numerical example, the first angular extension and/or the second angular extension 222, 224 may be in the range from 30° to 70°, for example in the range from 400 to 50°.

According to various aspects, the imaging optics 220 may be configured to project the collected light onto the array 212 of sensor pixels 214 with different magnifications in the two directions parallel to the axes of the array 212. Illustratively, the imaging optics 220 may be configured to project light onto the image sensor 210 with a first magnification in the first direction 252 and with a second magnification in the second direction 254. The imaging optics 220 may project light with a greater magnification in the direction of the main dimension/axis of the array 212. In the exemplary configuration in FIG. 2A, the imaging optics 220 may thus be configured to project light with a first magnification in the first direction 252 greater than the second magnification in the second direction 254.

By way of illustration, the imaging optics 220 may be configured to project onto the array 212 light collected from the first angular field of view with a first magnification factor, and may be configured to project onto the array 212 light collected from the second angular field of view with a second magnification factor. The magnification factor may be greater in correspondence of the main dimension of the array 212, e.g. in the exemplary scenario in FIG. 2A the first magnification factor may be greater than the second magnification factor. Considering for example an object in the scene, the imaging optics 220 may be configured to project light on the array 212 in such a way that the object is reproduced on the image plane (illustratively, on the sensor pixels 214) with a first size in the first direction 252 that is magnified by the first magnification factor compared to the actual size of the object, and with a second size in the second direction 254 that is magnified by the second magnification factor compared to the actual size of the object.

In general, the imaging optics 220 may be adapted to provide any suitable magnification factor depending on the overall geometry and configuration of the imaging device 200 and image sensor 210. In general, the first magnification factor in correspondence of the main axis of the array 212 may be greater than 0.1 for example the first magnification factor may be equal to or greater than 1, for example the first magnification factor may be equal to or greater than 10, for example the first magnification factor may be equal to or greater than 20. The second magnification factor in correspondence of the secondary axis of the array 212 may be greater than 0.1 for example the first magnification factor may be equal to or greater than 1, for example equal to or less than 10, for example equal to or less than 20. As a numerical example, the first magnification factor in correspondence of the main axis of the array 212 may be at least two times greater than the second magnification factor, for example at least five times greater, for example at least ten times greater.

The proposed configuration of the imaging optics 220 and image sensor 210 (with a high aspect ratio array) leads to an imaging process with higher object plane resolution along the main axis of the array 212 (e.g., the axis along the first direction 252) compared to the (lower) object plane resolution along the secondary axis of the array 212 (e.g., the axis along the second direction 254). Thus, while maintaining a design that makes the imaging device 200 suitable for integration in challenging (narrow) geometries, the imaging of angular field of view with a greater magnification on the main axis (and in some aspects with same angular extension on both axes) provides an optical performance that allows a sufficiently accurate identification/extraction of features from the scene, e.g. in combination with other imaging devices 200, as discussed in further detail below.

There may be various possible optical implementations to achieve the type of projection discussed above. According to various aspects, the imaging optics 220 may be configured to define different effective focal lengths for the imaging along the two axes of the array 212 of sensor pixels 214. Illustratively, the imaging optics 220 may be configured to define a first effective focal length 226 for imaging along the first direction 252 and a second effective focal length 228 for imaging along the second direction 254. Illustratively, the imaging optics 220 may be configured to define a first distance between the point of convergence of the imaging optics 220 for imaging the first angular field of view and the image sensor 210, and to define a second distance between the point of convergence of the imaging optics 220 for imaging the second angular field of view and the image sensor 210.

As known in the art, for a certain sensor size a shorter focal length corresponds to a larger angle of view. The imaging optics 220 may thus be configured to define a shorter focal length in correspondence of the short axis of the array 212, and a longer focal length in correspondence of the long axis of the array 212, e.g. to achieve the matching in angular extension in the two directions adjusted for the aspect ratio of the (rectangular) array 212. In the configuration in FIG. 2A and FIG. 2B, the first effective focal length 226 may thus be greater than the second effective focal length 228. The geometrical representations of the fields of view and of the effective focal lengths outlined in FIG. 2A and FIG. 2B serve the purpose of highlighting the relationship between effective focal length, field of view and magnification of a far object in a pinhole-camera-like representation. Understandably, a single ideal thin lens could not achieve the desired result, as two different effective focal lengths would necessarily result in two different back focal distances, preventing the formation of an image. However, the imaging optics 220 may include multiple optical surfaces that allow to have enough parameters at disposal in the system to define two effective focal lengths with the desired ratios, and at the same time match the image plane for the two sensor directions.

According to various aspects, the imaging optics 220 may be configured such that a relationship between the focal lengths 226, 228 corresponds to the aspect ratio of the array 212 of sensor pixels 214. Illustratively, a ratio of the second effective focal length 228 to the first effective focal length 226 may be equal to the aspect ratio of the array 212, e.g. may be equal to the ratio of the second number of sensor pixels 214 in the second direction 254 to the first number of sensor pixels 214 in the first direction 252 (and/or to the ratio of the second lateral dimension in the second direction 254 to the first lateral dimension in the first direction 252). The optical function implemented by the imaging optics 220 may thus be adapted to the geometry of the image sensor 210, to obtain the different magnifications along the two axes of the array 212 (and, in some aspects, to achieve the same angular extension for the angular field of view along the two axes). As known in the art, the angular field of view (AFOV) may be expressed via the equation AFOV=2*tan⁻¹(x/2f), where x is the dimension of the sensor and f is the focal length of the optics. Adapting f (in one direction) in a corresponding manner as x (in that direction) allows adapting the angular field of view (and correspondingly the field of view) in the two directions.

Considering an aspect ratio of the array 212 to be 1:N, the ratio of the effective focal lengths may be 1:N, so that at the lowest order of approximation the field of view of the imaging device 200 is the same in the two directions. Slight variations may be tolerated, e.g. in scenarios in which the angular field of view is slightly different in the two directions, or in scenarios in which the ratio of the effective focal lengths does not precisely match the aspect ratio of the array 212 (so that the image of the scene captured from the full field of view might not match exactly the sensor area).

The proposed configuration allows imaging a larger field of view rather than reducing the field of view to fit onto the stripe-shaped image sensor 210. Illustratively, imaging optics 220 that defines two different effective focal lengths leads to two different magnification factors in the two directions instead of a reduced field of view.

For systems configured to image far objects onto the back focal plane of the imaging system, the effective focal length defines the relationship between the object size in the field of view angular space and the image size on the sensor plane, therefore taking the role of the magnification factor in the context of the present disclosure. The first effective focal length 226 for imaging in the first direction 252 may be greater than or equal to 0.5 mm, for example may be greater than or equal to 5 mm, for example may be greater than or equal to 20 mm. The second effective focal length 228 for imaging in the second direction 254 may be greater than or equal to 0.5 mm, for example may be greater than or equal to 5 mm, for example may be greater than or equal to 20 mm.

The ratio between the first and second magnification factors, or equivalently, between the first and the second effective focal lengths, translates to a corresponding aspect ratio in the image proportions that are formed on the sensor by the optical system (i.e. the image aspect ratio). Matching the image aspect ratio with the sensor aspect ratio and selecting magnification values (or equivalently, EFL values for imaging far objects on the BFP of the optical system) ensures that the field of view in the two directions will be the same, as in the outlined preferred configuration.

In case of a mismatch, the sensor may be overfilled in at least one direction, leading to a slight mismatch in the effective field of view of the system, since part of the image will not be registered. Overfilling the sensor for part of the image sensor might be beneficial to prevent underfilling in other parts of the sensor. For instance, overfilling may allow to fill also the corner of the sensor in case of an elliptical pupil, as well as in case of distortions, such as pincushion or barrel distortions. Such optimizations and adjustments may be implemented in light of the system requirements, and do not invalidate the general idea discussed above. For instance, in such applications the imaging optics 220 may be configured to define a first and second field of view that differ by a factor between 0.55 and 1.8.

It may be understood that allowing for a slight mismatch between the magnification factor ratios and the sensor size ratios increases the flexibility in the fields of view.

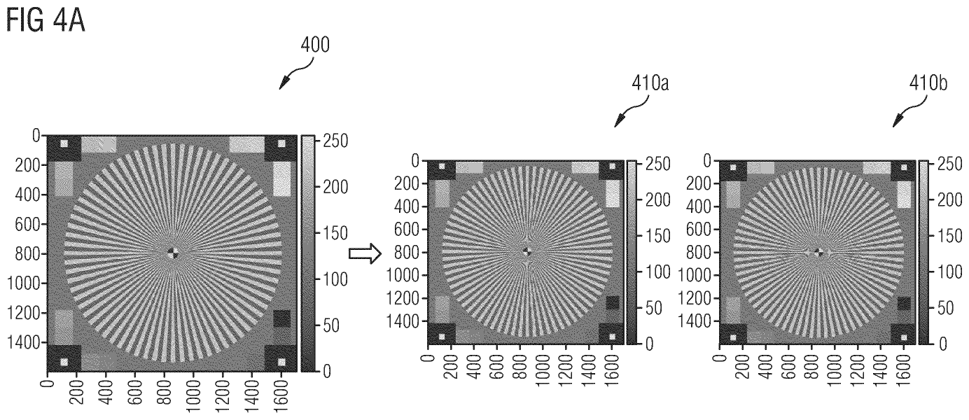

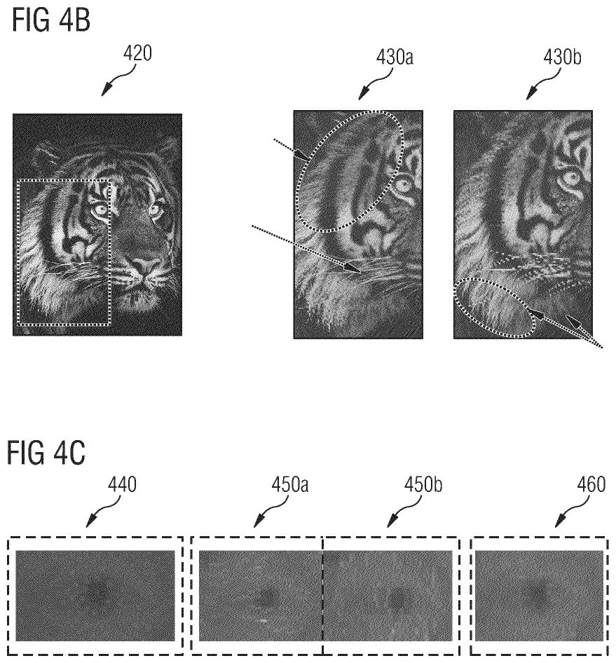

In the proposed configuration, the field of view is maintained in the two directions with the tradeoff of the image size. As illustrated in FIG. 2C, images collected by such imaging device 200 will have reduced resolution along one axis compared to a regular camera. In view of the aspect ratio of the image sensor 210, imaging the scene without reducing the angular field of view in the short axis leads to a reduced resolution along the short axis (illustratively, in view of the lower magnification). This, in turn opens the possibility of exploiting the higher resolution along the long axis for feature extraction (see also FIG. 4A to FIG. 4C). In this regard, FIG. 2C shows two diagrams 260a, 260b illustrating the same pattern as imaged via a regular full resolution camera (the first diagram 260a) in comparison with the pattern as imaged via an imaging device configured as described herein (the second diagram 260b). The diagram 260b in FIG. 2C refers to the exemplary case of a 1:8 aspect ratio for the array of sensor pixels. As shown, in the proposed configuration there is a squeezing of the field of view that leads to a reduced resolution along one axis compared to the case in which the pattern is imaged via a regular full resolution camera.

The imaging optics 220 may be implemented in any suitable manner, e.g. with any suitable combination of optical components to achieve the optical functionalities described herein. In an exemplary configuration, the imaging optics 220 may include optical components with different optical powers in the two directions 252, 254 and mix elements to reduce the optical barrel physical length (illustratively, the physical length of the imaging optics 220) to a length shorter than the (longest) first effective focal length in the first direction, and longer (or equal to) the (shorter) second effective focal length. Such a result can be obtained for example by mixing positive and negative elements with optical power in the first direction, for example as in a telephoto lens. Shortening the barrel length while maintaining large numerical apertures is also a desirable result for integrated optics commonly used, and the related developments can be translated in the imaging optics 220 using cylindrical elements instead of axially symmetric elements. The resulting optical barrel length can be longer compared to the second focal length. It is possible for example to maintain the design simple for elements with optical power in the second direction, accepting some degree of vignetting, especially when the required effective focal length ratios are closer to 1 (for example 1:2, 1:4). For example, taking advantage of the refractive index of components with optical power only in the first direction, as the refractive index of the corresponding material will reduce the propagation angles. It is possible for example, to use more optical elements, for instance with intermediate image planes.

As an example, the imaging optics 220 may include an astigmatic optical system, e.g. the imaging optics 220 may include one or more astigmatic lenses or an astigmatic stack of imaging optical lenses/components. An astigmatic optical system allows obtaining two different effective focal lengths 226, 228, e.g. to match or substantially match the aspect ratio of the array 212. For example, additionally or alternatively, the imaging optics 220 may include one or more cylindrical lenses, e.g. a system of cylindrical lenses, to image the field of view with different effective focal lengths in the two directions. As other examples, the imaging optics 220 may include biconic, toroidal, aspheric or freeform surface lenses, or combinations thereof, as well as elements composed of different materials, with different refractive indices for the wavelengths of interest. As a further example, additionally or alternatively, the imaging optics 220 may include one or more metalenses (illustratively one or more lens elements with a metasurface). The phase profiles of the metalenses may be designed (e.g., via simulations, or suitable algorithms) to obtain the same angular field of view with different magnifications (and different effective focal lengths) in the two directions. As a further example, additionally or alternatively, the imaging optics 220 may include diffractive lenses. The imaging optics 220 may also include microlens arrays. Such arrays may be designed and assembled to produce superposition compound lenses, sometimes referred to as the Gabor Superlenses. Additionally, optical components such as bandpass filters may be added to improve performance at the desired wavelengths, for instance in applications where active illumination is used. The entrance pupil and the footprint of the imaging optics 220 may differ in size and proportions compared to the module footprint or the sensor footprint. For example, the imaging optics footprint may be smaller than the sensor footprint.

FIG. 2D shows a simple illustrative example of a possible implementation of the imaging device 200 for a monochromatic application with low requirements in terms of image quality, compared to an RGB camera, making use of refractive components and a single lens material. In this regard, FIG. 2D shows three views 270a, 270b and 270c of the imaging device. It is understood that the representation in FIG. 2D is a simplified and schematic illustration to provide an understanding of the proposed strategy, and is not intended to be limiting. Illustratively, FIG. 2D shows a possible exemplary configuration of the imaging optics 220, but it is understood that other configurations with more, less, or alternative optical components may be provided to obtain different magnifications (and effective focal lengths) along the two directions.

In the three views, field rays 271 from an object located at infinity are represented for field angles 15°, 7.5° and 0°, defining a full angular field of view of about 30° in the two directions 252 and 254. The rays are projected on the image sensor 210. According to the exemplary configuration in FIG. 2D, the imaging optics 220 may include two (first) glass optical elements 272 and 273 with a first toroidal surface, with polynomial aspheric coefficients defined in the first direction 252 and each with a second biconic surface. The imaging optics 220 may further include a third lens element 274 with two toroidal surfaces, whose higher order polynomial parameters are in the first direction 252 for the first surface, and in the second direction 254 for the second surface. The geometric image analysis 280 shows the image projected from a square grid image centered at the 0° field. The results account for the distortion of the optics, and show an image aspect ratio close to 2.6. The geometric image analysis assumes a 10 micrometers pixel size, with an extension in the first direction 252 of 4.8 mm. The image plane resolution is, for this example, limited by the optical aberrations. It could be acceptable in some time of flight camera architectures, where blocks of individual photodetector pixels (for instance, single photon avalanche detectors), may be organized in macropixels whose outputs may for instance be connected to an OR logical tree. It is understood that the person skilled in the art of optical design may apply the general principles here exemplified to improve the overall quality of the image, reduce the device height in the optical axis direction 256, e.g., reduce vignetting in order to increase the relative illumination uniformity, or increase the device field of view.

According to various aspects, the imaging device 200 may further include a substrate 230 to provide mechanical support to the image sensor 210 and the imaging optics 220. The substrate 230 may be a rigid substrate or a flexible substrate. The substrate 230 may include or consist of any suitable material, e.g. depending on the intended application of the imaging device 200. For example, the substrate 230 may be a polymer substrate, a plastic substrate, a glass substrate, and the like. In some aspects, the imaging device 200 may further include a support structure 232 for accommodating the imaging optics 220. The support structure 232 may be configured to host the imaging optics 220 to provide a mechanical coupling of the optics with the rest of the imaging device 200. In some aspects, the support structure 232 (and optionally the substrate 230) may be opaque for light in the wavelength range in which the imaging device 200 should operate. Illustratively, the support structure 232 (and optionally the substrate 230) may be non-transmissive for light in the operating wavelength range of the imaging device (e.g., the visible range, or invisible range). This configuration may limit the influence of stray light on the detection process.

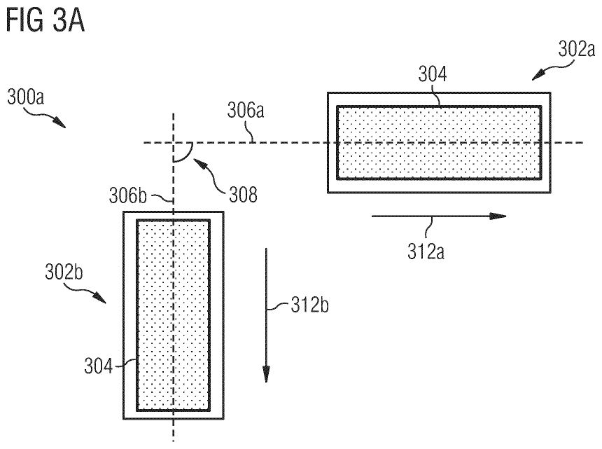

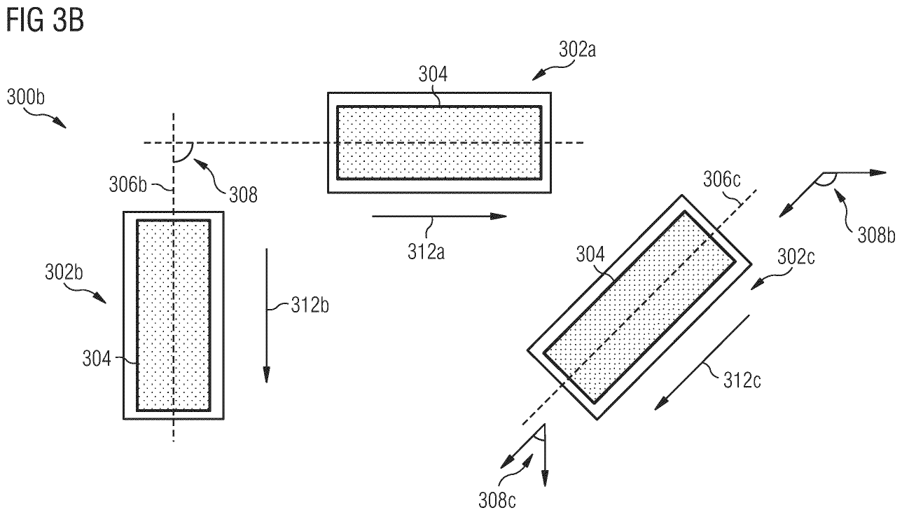

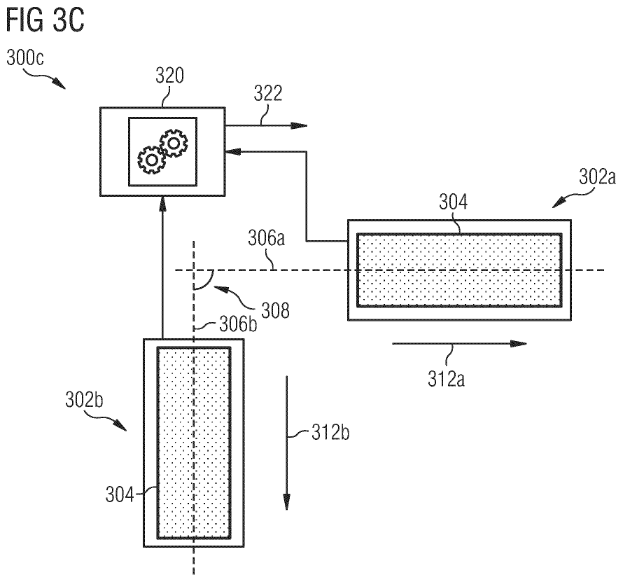

The capabilities of an imaging device configured as described herein may be complemented by using the imaging device in combination with further imaging devices, so as to exploit the respective high-resolution axes to gather a comprehensive understanding of the scene. In this regard, FIG. 3A to FIG. 3C show an imaging system 300a, 300b, 300c including a plurality of imaging devices 302a, 302b, 302c, according to various aspects. The imaging devices 302a, 302b, 302c may be configured as the imaging device 200 described in relation to FIG. 2A to FIG. 2D, and may include an array of sensor pixels (not shown) and a corresponding imaging optics 304 configured as discussed above. In the exemplary configurations in FIG. 3A to FIG. 3C an imaging system 300a with two imaging devices 302a, 302b, and an imaging system 300b with three imaging devices 302a, 302b, 302c are illustrated. It is however understood that in principle an imaging system as described herein may include any suitable number of imaging devices, e.g. two, three, four, five, ten, or more than ten.

As shown in FIG. 3A, the imaging system 300a may include two imaging devices 302a, 302b (a first imaging device 302a, and a second imaging device 302b). To exploit the different resolution capabilities, the imaging devices 302a, 302b may be disposed at different orientations, while facing the same field of view (illustratively, the same scene). This disposition allows using the imaging devices 302a, 302b to obtain images that have high resolution along different directions (illustratively, along the respective long axis of the imaging devices 302a, 302b). The proposed imaging system allows thus using stripe-shaped imaging devices 302a, 302b that may be integrated in narrow geometries, while still obtaining an overall suitable resolution for imaging the scene via the combined operation of the imaging devices 302a, 302b.

As shown in FIG. 3A, the first imaging device 302a may be oriented along a first orientation direction 312a and the second imaging device 302b may be oriented along a second orientation direction 312b. Illustratively, the imaging devices 302a, 302b may face towards the same direction (to collect light from the same scene) and may have the respective main dimension along the respective orientation direction. The (first) optical axis of the first imaging device 302a may be parallel to the (second) optical axis of the second imaging device 302b), e.g. both optical axes may be aligned along the same direction. The (first) main axis 306a of the array of sensor pixels of the first imaging device 302a may be along a first orientation direction 312a (illustratively, may be aligned with the first orientation direction 312a), and the main axis 306b of the array of sensor pixels of the second imaging device 302b may be along a second orientation direction 312b. Stated in a different fashion, each imaging device 302a, 302b may have a greater number of sensor pixels (and/or a greater lateral dimension) in the direction defined by the respective orientation direction compared to the number of sensor pixels (and/or lateral dimension) in the direction perpendicular to the orientation direction (in the plane perpendicular to the respective optical axis).

As mentioned, the imaging devices 302a, 302b may have different orientations. Illustratively, the respective orientation directions (and, accordingly, the respective main axes) may be at an angle with one another. With reference to FIG. 3A, the first orientation direction 312a (and the first main axis 306a) may be at an angle 308 with respect to the second orientation direction 312b (and the second main axis 306b). The angle at which two imaging devices 302a, 302b are disposed may be adapted depending on system considerations, such as the geometry of a host device, the type of features relevant for the desired application, and the like.

In general, the angle 308 formed between the orientations of imaging devices 302a, 302b may be any macroscopic angle greater than 0° (and less than 180°). In a preferred configuration, as shown in FIG. 3A, the first orientation direction 312a may be orthogonal to the second orientation direction 312b (the angle 308 may be 90°). This configuration allows extracting horizontal features and vertical features from the field of view, as discussed in further detail below, which may in general be the most relevant type of features in a scene. However, the angle may be freely adapted depending on the desired configuration. As a numerical example, the angle 308 between the first orientation direction 312a and the second orientation direction 312b may be in the range from 10° to 150°, for example in the range from 20° to 120°, for example in the range from 30° to 60°.

As mentioned above, the configuration of the imaging system 300a may be extended to include more than two imaging devices 302a, 302b. As an example, as shown in FIG. 3B, the imaging system 300b may include a third imaging device 302c. The third imaging device 302c may face towards the same direction as the first imaging device 302a and second imaging device 302b (e.g., the (third) optical axis of the third imaging device 302c may be parallel to the optical axes of the first imaging device 302a and second imaging device 302b). The third imaging device 302c may be oriented along a third orientation direction 312c, illustratively a (third) main axis 306c of the array of sensor pixels of the third imaging device 302c may be along a third orientation direction 312c. The third orientation direction 312c may be different from the first and second orientation directions. Illustratively, the third orientation direction 312c may be at an angle 308b with the first orientation direction 312a, and at a further angle 308c with the second orientation direction 312. The angle 308b and the further angle 308c may be greater than 0° (and less than 180°), and may both be different from the angle 308 between the first imaging device 302a and the second imaging device 302b. The configuration in FIG. 3B may be further extended to a fourth imaging device at a fourth orientation direction, etc.

In general, the imaging devices 302a, 302b, 302c may have a same configuration, e.g. the same aspect ratio, the same operating wavelength, etc. However, in principle an imaging system 300a, 300b may also include imaging devices 302a, 302b, 302c with a different configuration, e.g. to tailor the individual properties according to system considerations. For example, imaging devices 302a, 302b, 302c with different aspect ratios may be provided, e.g. to adapt the individual geometries to the structure of a host device in which the imaging system 300a, 300b should be integrated. As another example, imaging devices 302a, 302b, 302c with different operating wavelengths may be provided, e.g. to adapt the individual light detection to expected wavelengths of received light (e.g., according to known emission wavelengths).

According to various aspects, a first aspect ratio of the first imaging device 302a may be different from a second aspect ratio of the second imaging device 302b (and/or from a third aspect ratio of the third imaging device 302c, etc.). Illustratively, a ratio of the (second) number of sensor pixels of the array of the first imaging device 302a along the respective minor axis to the (first) number of sensor pixels of the array along the respective main axis may be different from a ratio of the (second) number of sensor pixels of the array of the second imaging device 302a along the respective minor axis to the (first) number of sensor pixels of the array along the respective main axis. Stated differently, a ratio of the (second) lateral dimension of the array of the first imaging device 302a along the respective minor axis to the (first) lateral dimension of the array along the respective main axis may be different from a ratio of the (second) lateral dimension of the array of the second imaging device 302a along the respective minor axis to the (first) lateral dimension of the array along the respective main axis.

According to various aspects, additionally or alternatively, the first imaging device 302a may be configured to operate in a first wavelength range, and the second imaging device 302b may be configured to operate in a second wavelength range different from the first wavelength range (and/or different from a third wavelength range in which the third imaging device 302c is configured to operate, etc.). At least one sensor pixel (e.g., each sensor pixel) of the first imaging device 302a may be configured to be sensitive for light in the first wavelength range, and at least one sensor pixel (e.g., each sensor pixel) of the second imaging device 302a may be configured to be sensitive for light in the second wavelength range. For example, the first imaging device 302a may be configured to operate in the visible wavelength range and the second imaging device 302b may be configured to operate outside of the visible wavelength range (e.g., in the infrared range or ultraviolet range). As another example, the first imaging device 302a may be configured to operate around a first wavelength (e.g., red) and the second imaging device 302b may be configured to operate around a second wavelength (e.g., green). The third imaging device 302b may be configured to operate around a third wavelength (e.g., blue), etc.

According to various aspects, the imaging system may further include a shared control unit (e.g., as part of a processing circuit 320), responsible for control and synchronization of different imaging devices 302a, 302b, 302c on the same system. Such a unit can be an external unit producing synchronized trigger signals. Additionally or alternatively, one or more imaging devices 302a, 302b, 302c in the imaging system may include a unit responsible of controlling the device itself and simultaneously send clock or trigger signals to the control units of the other imaging devices.

According to various aspects, the images obtained via the different imaging devices 302a, 302b, 302c may be processed to obtain information about the scene, e.g. for extracting features of interest, for tracking, depth sensing, and the like. In this regard, the imaging system 300c may include a processing circuit 320 configured to receive image data from the imaging devices 302a, 302b, 302c and carry out a processing of the image data, as shown in FIG. 3C. The exemplary configuration in FIG. 3C shows the scenario in which the imaging system 300c includes two imaging devices 302a, 302b oriented at 900 with respect to one another. It is however understood that the aspects discussed in relation to FIG. 3C apply in a corresponding manner to a configuration with more than two imaging devices 302a, 302b, and/or to a configuration with imaging devices 302a, 302b oriented at a different angle, as discussed in relation to FIG. 3A and FIG. 3B.

In general, the processing circuit 320 may be configured to receive image data from the imaging devices (e.g., first image data from the first imaging device 302a, second image data from the second imaging device 302b, etc.), and may be configured to determine image information of a field of view of the imaging system 300c based on the received image data (e.g., the received first image data and the second image data). In this regard, the term “image data” may describe data or information representative of light received/detected at an imaging device 302a, 302b. Illustratively, the “image data” from an imaging device 302a, 302b may represent one or more properties of light received/detected at the sensor pixels of that imaging device 302a, 302b. For example, the “image data” may represent an intensity of the light, a wavelength of the light, a phase of the light, an arrival time of the light, and the like. For example, the image data from an imaging device 302a, 302b may include the detection signals generated by the sensor pixels of that imaging device 302a, 302b.

The term “image information” may describe any type of information that may be derived about the field of view from the image data delivered by the imaging devices 302a, 302b. Illustratively, “image information” may describe any suitable information representative of properties of one or more objects in the field of view of the imaging system. For example, the “image information” may represent the presence of an object, the motion of an object, the size of an object, one or more features of the object, a color of the object, and the like. The field of view of the imaging system 300c may include the fields of view of the imaging devices 302a, 302b composing the imaging system 300c. The individual fields of view may substantially correspond to one another, e.g. may substantially (fully) overlap.

In general, the processing circuit 320 may be configured to carry out a digital processing of the image data. For example, each imaging device 302a, 302b may include an analog-to-digital converter configured to convert the analog detection signals (e.g., currents or voltages) into corresponding digital signals for processing by the processing circuit 320. As another example, the processing circuit 320 may be coupled with an analog-to-digital converter (or a plurality of analog-to-digital converters) at which analog image data are received and converted into corresponding digital image data. It is however understood that, in principle, the processing circuit 320 may also be configured to carry out analog signal processing of analog image data.

In some aspects, the processing circuit 320 may be a dedicated component of the imaging system 300c. In other aspects, the processing circuit 320 may be programmed to execute further functions in addition to the image processing. For example, the processing circuit 320 may be a processor of a host device in which the imaging system 300c is integrated (e.g., the processor of a mobile communication device, or of a display device, or of a wearable device, as examples). The processing circuit 320 may be configured to generate an output signal 322 representative of the image information. The output signal 322 may be used for further processing, e.g. to generate instructions in a host device, to trigger a certain action, and the like. For example, the processing circuit 320 may deliver the output signal 322 to another circuit of the host device. The processing circuit 320 may thus collect an input image from each camera (or from a subset of the available cameras) and compose an output image or some other output quantity for a dedicated use case (e.g., hand pose in hand tracking). The processing (and merging) of the individual data may mitigate the downscaling effect related to the aspect ratio of the image sensors and still enable a comprehensive characterization of the field of view.

The combined processing of image data from imaging devices oriented at different angles allows compensating the low resolution of one imaging device (along the respective short axis) with the image data from the other imaging device(s), thus enabling a comprehensive characterization of the field of view. The proposed approach exploits thus the high aspect ratio of the individual cameras (e.g., the corresponding aspect ratio in effective focal lengths), and also the processing (e.g., based on software) to use inputs from different cameras to compensate for the performance reduction of such individual camera modules along the low-resolution direction. The proposed solution solves the problem of a “low y-axis footprint” of a few differently oriented cameras.

In general, the processing circuit 320 may be configured to carry out the processing of the image data using any suitable processing algorithm, e.g. any suitable processing software to integrate the outputs of the cameras, e.g. to reconstruct the field of view and/or to extract specific features from the image data. The particular algorithm may be selected depending on the end application or specific use case. For example, the processing circuit 320 may be configured to use one or more machine learning models to process the image data. The term “model” may be describe any kind of algorithm configured to receive input data and deliver corresponding output data. A “machine learning model” may have adjustable parameters that may be tuned during a training phase based on training data (e.g., image data representing known scenarios or known objects). The processing circuit 320 may apply the trained machine learning model during an inference phase to determine the image information for the field of view. A machine learning model may be trained and configured in any suitable manner, e.g. a machine learning model may be based on supervised learning, semi-supervised learning, unsupervised learning, reinforcement learning, etc.

In an exemplary configuration, a machine learning model used by the processing circuit 320 may include a neural network. The neural network may have any suitable configuration, e.g. convolutional neural network, recurrent neural network, generative adversarial network, feed forward neural network, multilayer perceptron, modular neural network, and the like. The neural network may include any number of layers. The training of the neural network may be based on any kind of training algorithm, e.g. backpropagation. Training data may be synthetically generated from ground truth images, based on the knowledge of the optical and sensor resolution, magnification factors, and other camera and sensor parameters, including but not limited to intrinsic and extrinsic camera parameters.

The processing circuit 320 may apply any suitable image processing algorithm for processing (e.g., combining) the image data. As examples, the processing circuit 320 may apply a contrast enhancement algorithm, a histogram equalization algorithm, a dithering algorithm, an error diffusion algorithm, a feature detection algorithm (e.g., canny edge detector algorithm, Hough transform algorithm, scale-invariant feature transform algorithm, speeded up robust features algorithm, etc.), a blind deconvolution algorithm, a segmentation algorithm (e.g., random walker algorithm, region growing algorithm, etc.), an interpolation algorithm, a Fourier filtering algorithm, and the like.

In general, the processing of the image data may be adapted depending on the type of image information to be extracted from the image data. In an exemplary configuration, the processing circuit 320 may be configured to combine the image data from the different imaging devices 302a, 302b (e.g., the first image data and second image data) to reconstruct an image of the field of view of the imaging system 300c. Illustratively, the processing circuit 320 may be configured to combine (e.g., merge) the high resolution data from the various imaging devices 302a, 302b to compensate the respective low resolution data and reconstruct a full image of the field of view. In a simple configuration, the processing circuit 320 may be configured to combine the image data by averaging light intensity values from the image data to deliver a reconstructed image of the field of view as an average of the different individual images delivered by the imaging devices 302a, 302b.

Aspects of the present disclosure may be based on the realization that the differently oriented imaging devices 302a, 302b may deliver relatively high resolution information about features in the field of view that have an orientation compatible with the orientation of the imaging devices 302a, 302b. Illustratively, some aspects may be based on the realization that each imaging device 302a, 302b may allow high resolution imaging of features that should be distinguished in the direction parallel to the main axis (high resolution axis) of the array of sensor pixels of the imaging device 302a, 302b. Thus, considering a certain orientation direction, the imaging device 302a, 302b may enable separating/distinguishing features along that orientation direction with high resolution, with the tradeoff of a low(er) resolution for separating/distinguishing features along the perpendicular direction (illustratively, the direction of the secondary axis).

Based on these considerations, the processing circuit 320 may be configured to identify (e.g., extract) visual features from the field of view of the imaging system 300c using the image data (e.g., first and/or second image data). In this context, the term “visual” may refer to any type of features that may be characterized via an imaging process. As mentioned above, the imaging devices 302a, 302b may operate in the visible wavelength range or outside the visible wavelength range. Thus reference to the “visual” nature of a feature may apply both to the case in which the feature is actually visible to the human eye and to the case in which the feature is invisible to the human eye (e.g., in case the feature is used for sensing processes, such as face recognition, object recognition, and the like, for which infrared light may be used).

In general, the processing circuit 320 may be configured to use image data from an imaging device 302a, 302b disposed along a certain orientation direction to identify (e.g., extract) features in the field of view that extend in a direction substantially perpendicular to that orientation direction. Illustratively, the processing circuit 320 may be configured to use image data from an imaging device 302a, 302b disposed along a certain orientation direction to identify (e.g., extract) features in the field of view that are separable (and separated from one another) along that orientation direction. For example, considering the exemplary configuration in FIG. 3C, the processing circuit 320 may be configured to select (and use) the first image data to identify visual features that extend in a direction perpendicular to the first orientation direction 312a (in the plane perpendicular to the optical axis of the first imaging device 302a), e.g. features that are spatially distributed along the first orientation direction 312a. In a corresponding manner, the processing circuit 320 may be configured to select (and use) the second image data to identify visual features that extend in a direction perpendicular to the second orientation direction 312b (in the plane perpendicular to the optical axis of the second imaging device 302b), e.g. features that are distributed along the second orientation direction 312b.

In particular, the image data from an imaging device 302a, 302b may be suitable for identifying linear features, e.g. features that extend along a substantially linear direction in the field of view (see also FIG. 4B). The use of different image data from the different imaging devices 302a, 302b allows thus complementing the individual capabilities to identify different types of features within the field of view. The other features that are not distributed along an orientation direction of an imaging device 302a, 302b may still be identified with an intermediate resolution.

As an example, the processing circuit 320 may be configured to carry out a tracking of one or more identified features in the field of view of the imaging system 300c. Illustratively, the processing circuit 320 may be configured to follow an evolution of a spatial position of the one or more identified features over time, e.g. to associate two-dimensional coordinates or three-dimensional coordinates corresponding to a position of the one or more identified features to a respective time point. The tracked features may be any suitable feature or object of interest, such as the hand of a user, the eyes of a user, a vehicle, an animal, etc.

As another example, additionally or alternatively, the processing circuit 320 may be configured to calculate a time-of-flight associated with one or more identified features, and accordingly a depth of the one or more identified features (illustratively, a distance along the direction parallel to the optical axis of the imaging system). The processing circuit 320 may receive a signal indicative of an emission time of the light and may identify a time of arrival of light at the imaging system 300c based on the image data delivered by the imaging devices 302a, 302b. This configuration may be provided, for example, for mapping the presence of objects in the field of view, and their properties such as distance from the host device, speed, direction of motion, and the like.

As a further example, additionally or alternatively, the processing circuit 320 may be configured to determine (e.g., estimate, measure) the distortion of a predefined light pattern (e.g., a grid of light dots for example) based on the image data delivered by the imaging devices 302a, 302b. This configuration may be provided, for example, for face-recognition applications, in which the distortion of the emitted pattern is associated to the profile of an object (e.g., a person) in the field of view of the imaging system 300c. For example, the processing circuit 320 may be configured to reconstruct a shape of the object (e.g., a face) based on the distorted pattern.

According to various aspects, the processing circuit 320 may be configured to adapt the processing based on known or expected features in the field of view. For example, the processing circuit 320 may be configured to logically divide the field of view of the imaging system 300c in a plurality of regions based on the type of visual features present in each region. Illustratively, the processing circuit 320 may be configured to subdivide the field of view in areas of interest based on the direction along which the features in those areas are distributed and/or the direction along which the features in those areas extend/are oriented. The logical division may be based on predefined information available to the processing circuit 320, and/or may be based on a previous iteration of the imaging process in which features have been identified/extracted.

The processing circuit 320 may thus be configured to select the image data from an imaging device 302a, 302b to determine image information about one of the regions into which the field of view is logically divided based on the type of visual features present in that region, e.g. based on which features are predominantly present in that region. For example, the processing circuit 320 may be configured to select (and use) the first image data and/or the second image to determine image information about one of the regions depending on whether the features in that region are distributed along the first orientation direction or second orientation direction, e.g. depending on whether the features in that region are oriented along the second orientation direction or along the first orientation direction.

According to various aspects, the processing circuit 320 may be configured to pre-process the image data prior to determining the image information, e.g. the processing circuit 320 may be configured to carry out a pre-processing of the first image data and/or the second image data prior to using the first image data and/or the second image data to determine the image information of the field of view of the imaging system 300c. In general, the pre-processing may ensure that the image data from different imaging devices 302a, 302b may be suitably combined. For example, the processing circuit 320 may be configured to map spatial coordinates of image data from an imaging device (e.g., the first image data from the first imaging device 302a) to spatial coordinates of image data from another imaging device (e.g., the second image data from the second imaging device 302b). Illustratively, the processing circuit 320 may be configured to assign values/information that in the image data have different spatial coordinates to the same spatial coordinate in the field of view.

The mapping may be based on known system properties. For example, the processing circuit 320 may be configured to map the image data to the spatial coordinates of the field of view based on the relative position of the imaging devices 302a, 302b with respect to one another. The processing circuit 320 may thus carry out a baseline correction to compensate for the different orientation and relative distance between imaging devices 302a, 302b. By way of illustration, the processing circuit may be configured to compensate the distance and different orientation between the imaging devices 302a, 302b to match the respective image data with one another. In an exemplary configuration, in case the imaging devices 302a, 302b have different aspect ratios, the processing circuit 320 may be further configured to compensate for the different aspect ratios to match the image data with one another.

In an exemplary configuration, the imaging system 300c may further include a light emission system (not shown) or may operate in combination with a light emission system. The light emission system may be configured to emit light into the field of view. Illustratively, the light emission system may emit light in a field of illumination that overlaps (fully, or at least in part) with the field of view of the imaging system 300c. The light emission system may include emitter optics (e.g., one or more lenses, one or more mirrors, and the like) and a light source configured to emit light in a predefined wavelength range. As an example, the light source may be or include a laser source, e.g. a Vertical Cavity Surface Emitting Laser (VCSEL) or a VCSEL array. The light source may be configured to emit light having a predefined wavelength, illustratively in the same wavelength range or ranges for which the imaging devices 302a, 302b are sensitive.

The light source may be configured to emit light in any suitable manner depending on the overall configuration of the imaging system 300c. As an example, the light source may emit continuous light. As another example, the light source may emit light in a pulsed manner (e.g., for time-of-flight measurements), e.g. the light source may emit a sequence of light pulses. As a further example, the light emission system may emit light according to a predefined pattern, e.g. a grid of light dots. In an exemplary configuration, the processing circuit 320 may be configured to control the light emission by the light source, e.g. the processing circuit 320 may be configured to instruct or cause the light emission, e.g. at a certain time point, at certain time intervals, in response to a certain event, and the like. For example, the light source may be configured to emit a pattern that is configured to take advantage of the camera configuration proposed herein, thus exploiting the finer object space resolution in the longer direction of the image sensors. For example, the light source may be configured to emit a pattern composed of parallel lines orthogonal to the longer direction of one or more of the imaging devices of the image system, for example with additional information encoded into the distribution of lines. Furthermore, in some aspects the system may further include one or more elements whose baseline with respect to one or more camera comprising the system is along the higher resolution direction, to maintain a high accuracy for depth determination.

FIG. 4A to FIG. 4C show various images to illustrate the feature identification/extraction with an imaging system configured as described herein. The images and patterns in FIG. 4A to FIG. 4C refer to the exemplary case in which the imaging system includes two imaging devices oriented at a 900 angle with respect to one another (as in FIG. 3A and FIG. 3C). In particular, the images and patterns in FIG. 4A to FIG. 4C refer to the exemplary case in which one imaging device is oriented parallel to the horizontal field of view (referred to also as horizontal camera) and the other imaging device is oriented parallel to the vertical field of view (referred to also as vertical camera). It is however understood that the aspects discussed in relation to FIG. 4A to FIG. 4C may apply in a corresponding manner to other configurations of the imaging system, e.g. with more than two imaging devices, with different orientations, etc.

FIG. 4A shows a diagram 400 with a pattern corresponding to a world scene, and the corresponding images 410a, 410b obtained with an imaging device oriented parallel to the vertical field of view (a first diagram 410a) and with an imaging device oriented parallel to the horizontal field of view (a second diagram 410b). In this exemplary case, an aspect ratio of 1:8 for the image sensors is considered. The patterns shown in the first diagram 410a and in the second diagram 410b are stretched to the original aspect ratio of the scene, but one axis has a much lower resolution. Illustratively, for the first diagram 410a corresponding to the vertical camera, the imaged pattern has a resolution along the vertical direction higher than along the horizontal direction, thus allowing to distinguish/separate features distributed along the vertical direction. In a corresponding manner, for the second diagram 410b corresponding to the horizontal camera, the imaged pattern has a resolution along the horizontal direction higher than along the vertical direction, thus allowing to distinguish/separate features distributed along the horizontal direction.

FIG. 4B shows an exemplary original image 420 and corresponding images obtained with an imaging device oriented parallel to the vertical field of view (a first image 430a) and with an imaging device oriented parallel to the horizontal field of view (a second image 430b). The first and second images 430a, 430b correspond to the portion of the original image 420 enclosed in the rectangular area. In this exemplary case, an aspect ratio of 1:8 for the image sensors is considered. As shown, if large but linear features are present in the scene, the two cameras may show different performance for different parts of the image, so that one of the imaging devices may be selected for imaging a respective region (or portion) of the field of view, rather than merely merging the image data. In the exemplary case in FIG. 4B, the whiskers of the tiger and the horizontal patterns of the fur (indicated by the arrows in the first diagram 430a) are better resolved in the vertical camera. On the other hand, the horizontal camera may better retain information on the vertical patterns (indicated by the arrows in the second diagram 430b). For example, this approach may also be used in a RGB camera.

FIG. 4C shows an exemplary original image 440 with an enlarged feature (e.g., an eye), and corresponding images of the enlarged feature obtained with an imaging device oriented parallel to the vertical field of view (a first image 450a) and with an imaging device oriented parallel to the horizontal field of view (a second image 450b). Furthermore, FIG. 4C shows a resulting image 460 of the enlarged feature obtained as a geometrical average of the first image 450a and second image 450b. As shown, small features along the axes and diagonals may be degraded. For such cases, the processing algorithm may be adapted, e.g. based on learning-based approaches, and tailored to the specific use case to allow for a more detailed reconstruction of the field of view. An optimization of the illumination pattern for the specific case may also lead to better results. As mentioned, there are applications that do not suffer from this drawback, e.g. in case data are integrated over a few pixels (such as for direct time of flight), or in case the output is some other metadata (e.g., for tracking).

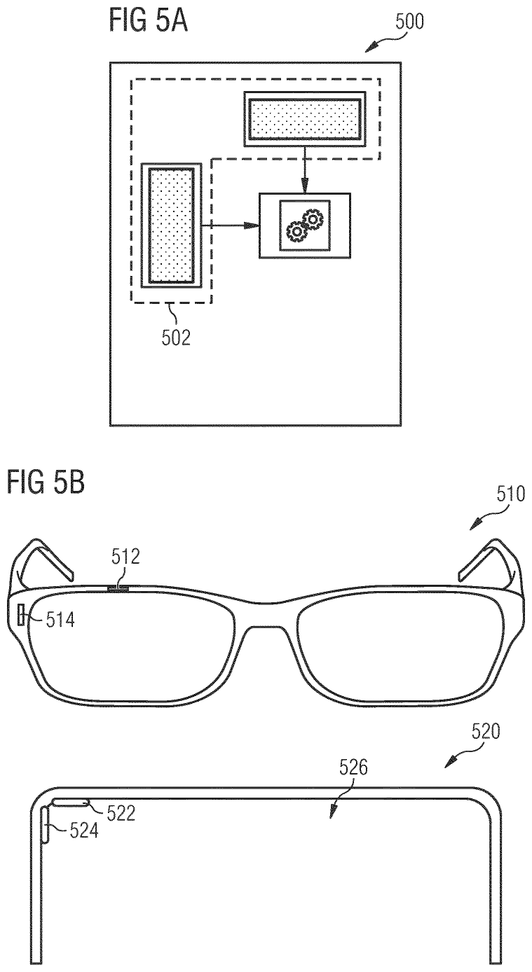

According to various aspects, an imaging system as described herein may be integrated in a host device, as shown in FIG. 5A and FIG. 5B. In this regard, FIG. 5A shows a host device 500 including an imaging system 502. The imaging system 502 may be configured as the imaging system 300a, 300b, 300c discussed in relation to FIG. 3A to FIG. 3C. The exemplary configuration in FIG. 5A and FIG. 5B shows an imaging system 502 with two imaging devices oriented at a 900 angle with respect to one another (as in FIG. 3A and FIG. 3C), and including a processing circuit. It is however understood that the aspects discussed in relation to FIG. 5A and FIG. 5B may apply in a corresponding manner to other configurations of the imaging system, e.g. with more than two imaging devices, with different orientations, etc.

In general, the host device 500 may be any suitable device that may exploit the imaging capabilities of the imaging system 502, e.g. to implement one or more functionalities. As an example, the host device 500 may use the imaging system 502 for face authentication. As another example, the host device 500 may use the imaging system 502 for feature tracking. As a further example, the host device 500 may use the imaging system 502 for depth sensing. In this connection, a central processing system of the host device 500 may receive the output signal from the processing circuit of the imaging system 502, or may directly receive image data from the imaging devices and carry out the image processing described in relation to FIG. 3C.

In general, the host device 500 may be any suitable type of device, e.g. a portable device, a mobile communication device, a wearable device, and the like. For example, the host device 500 may be a device having a narrow support structure or frame structure in which the imaging system 502 may be integrated. As examples, the host device 500 may be a mobile phone, a tablet, a laptop, a wearable electronic device (such as smart glasses, VR/AR glasses, an armband, a headband, etc.), a smart house appliance (such as a smart television, a smart thermometer, etc.), a gaming console, a small vehicle (e.g., a drone), a cleaning robot, and the like. In some aspects, the host device 500 may be a VR device and/or AR device.

In principle, the imaging devices may be disposed in any suitable portion of the host device 500, e.g. depending on the overall geometry or design of the host device. In general, the aspect ratio of the imaging devices makes them suitable for integration in narrow spaces. As an example, the imaging devices may be disposed in a frame, or border portion, of the host device 500. In an exemplary configuration, a first imaging device may be disposed in a first portion of a frame of the host device 500, a second imaging device may be disposed in a second portion of a frame of the host device 500, etc. For example, the imaging devices may be disposed in the region surrounding a display area of the host device, or in the region surrounding a light-transmissive region of the host device. FIG. 5B shows two exemplary host devices 510, 520 in which the imaging system may be integrated. As a first example, the imaging devices 512, 514 may be integrated in the frame of a pair of glasses 510, e.g. around a lens. As another example, the imaging devices 522, 524 may be integrated at the corners of a display area 526 of a mobile communication device 520, e.g. a smartphone or tablet.

The term “processing circuit” as used herein may be understood as any kind of technological entity that allows handling of data. The data may be handled according to one or more specific functions that the processing circuit may execute. Further, a processing circuit as used herein may be understood as any kind of circuit, e.g., any kind of analog or digital circuit. A processing circuit may thus be or include an analog circuit, digital circuit, mixed-signal circuit, logic circuit (e.g., a hard-wired logic circuit or a programmable logic circuit), microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. It is understood that any two (or more) of the processing circuits detailed herein may be realized as a single entity with equivalent functionality or the like, and conversely that any single processing circuit detailed herein may be realized as two (or more) separate entities with equivalent functionality or the like.

The word “exemplary” is used herein to mean “serving as an example, instance, or illustration”. Any embodiment or design described herein as “exemplary” is not necessarily to be construed as preferred or advantageous over other embodiments or designs.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

All acronyms defined in the above description additionally hold in all claims included herein.

While the invention has been particularly shown and described with reference to specific aspects, it should be understood by those skilled in the art that various changes in form and detail may be made therein without departing from the scope of the invention as defined by the appended claims. The scope of the invention is thus indicated by the appended claims and all changes, which come within the meaning and range of equivalency of the claims, are therefore intended to be embraced.

List of reference signs

| | |
|---|---|
| 100 | Image sensor |
| 102 | Array of sensor pixels |
| 104 | Sensor pixel |
| 106 | Substrate |
| 108 | First lateral dimension |
| 110 | Second lateral dimension |
| 112 | First axis |
| 114 | Second axis |
| 152 | First direction |
| 154 | Second direction |
| 156 | Third direction |
| 200 | Imaging device |
| 210 | Image sensor |
| 212 | Array of sensor pixels |
| 214 | Sensor pixel |
| 216 | Substrate |
| 220 | Imaging optics |
| 222 | First angular extension |
| 224 | Second angular extension |
| 226 | First effective focal length |
| 228 | Second effective focal length |
| 230 | Substrate |
| 232 | Support structure |
| 252 | First direction |
| 254 | Second direction |
| 256 | Third direction |
| 260a | First diagram |
| 260b | Second diagram |
| 270a | First view |
| 270b | Second view |
| 270c | Third view |
| 271 | Field rays |
| 272 | Optical element |
| 273 | Optical element |
| 274 | Lens element |
| 280 | Geometric image analysis |
| 300a | Imaging system |
| 300b | Imaging system |
| 300c | Imaging system |
| 302a | First imaging device |
| 302b | Second imaging device |
| 302c | Third imaging device |
| 304 | Imaging optics |
| 306a | First main axis |
| 306b | Second main axis |
| 306c | Third main axis |
| 308 | Angle |
| 308b | Angle |
| 308c | Angle |
| 312a | First orientation direction |
| 312b | Second orientation direction |
| 312c | Third orientation direction |
| 320 | Processing circuit |
| 322 | Output signal |
| 400 | Diagram |
| 410a | First diagram |
| 410b | Second diagram |
| 420 | Image |
| 430a | First image |
| 430b | Second image |
| 440 | Image |
| 450a | First image |
| 450b | Second image |
| 460 | Geometrical average |
| 500 | Host device |
| 502 | Imaging system |
| 510 | Host device |
| 512 | First imaging device |
| 514 | Second imaging device |
| 520 | Host device |
| 522 | First imaging device |
| 524 | Second imaging device |
| 526 | Display area |

1. An imaging device comprising:
an image sensor comprising an array of sensor pixels,
wherein the array of sensor pixels has a first lateral dimension in a first direction and second lateral dimension in a second direction orthogonal to the first direction, wherein the first lateral dimension is greater than the second lateral dimension; and
imaging optics configured to collect light and project the collected light onto the array of sensor pixels,
wherein the imaging optics is configured to project the collected light onto the array of sensor pixels with a first magnification in the first direction and with a second magnification in the second direction, wherein the first magnification is greater than the second magnification,
wherein a ratio of the second magnification to the first magnification is equal to a ratio of the second lateral dimension in the second direction to the first lateral dimension in the first direction.

2. (canceled)

3. The imaging device according to claim 1,
wherein the imaging optics is configured to define a first effective focal length for imaging in the first direction and a second effective focal length for imaging in the second direction,
wherein a ratio of the second effective focal length to the first effective focal length is equal to a ratio of the second lateral dimension in the second direction to the first lateral dimension in the first direction.

4. The imaging device according to claim 1,
wherein the imaging optics is further configured to define a first angular field of view in the first direction and a second angular field of view in the second direction, and
wherein a ratio between a first angular extension of the first angular field of view and a second angular extension of the second angular field of view is in the range from 0.55 to 1.8.

5. The imaging device according to claim 4,
wherein the first angular field of view and the second angular field have a same angular extension.

6. The imaging device according to claim 1,
wherein at least one sensor pixel is configured to be sensitive for light in a first wavelength range;
wherein at least one other sensor pixel is configured to be sensitive for light in a second wavelength range, and
wherein the first wavelength range is different from the second wavelength range.

7. The imaging device according to claim 1,
wherein an aspect ratio defined as a ratio of the second lateral dimension in the second direction to the first lateral dimension in the first direction is in the range from 1:2 to 1:10.

8. An imaging system comprising:
a first imaging device according to claim 1;
a second imaging device according to claim 1;
wherein the first imaging device and the second imaging device face towards the same direction,
wherein a first main dimension of the array of sensor pixels of the first imaging device is along a first orientation direction;
wherein a second main dimension of the array of sensor pixels of the second imaging device is along a second orientation direction; and
wherein the first orientation direction is at an angle greater than 0° and less than 180° with the second orientation direction.

9. The imaging system according to claim 8,
wherein the first orientation direction is orthogonal to the second orientation direction.

10. The imaging system according to claim 8, further comprising:
a third imaging device comprising:
an image sensor comprising an array of sensor pixels,
wherein the array of sensor pixels has a first lateral dimension in a first direction and second lateral dimension in a second direction orthogonal to the first direction, wherein the first lateral dimension is greater than the second lateral dimension; and
imaging optics configured to collect light and project the collected light onto the array of sensor pixels,
wherein the imaging optics is configured to project the collected light onto the array of sensor pixels with a first magnification in the first direction and with a second magnification in the second direction, wherein the first magnification is greater than the second magnification,
wherein a ratio of the second magnification to the first magnification is equal to a ratio of the second lateral dimension in the second direction to the first lateral dimension in the first direction;
wherein a third main dimension of the array of sensor pixels of the third imaging device is along a third orientation direction,
wherein the first orientation direction is at an angle greater than 0° and less than 180° with the third orientation direction, and
wherein the second orientation direction is at an angle greater than 0° and less than 180° with the third orientation direction.

11. The imaging system according to claim 8, further comprising:
a processing circuit configured to:
receive first image data from the first imaging device and second image data from the second imaging device; and
determine image information of a field of view of the imaging system based on the first image data and the second image data.

12. The imaging system according to claim 11,
wherein the processing circuit is configured to select one of the first image data or the second image data to identify visual features in the field of view of the imaging system,
wherein processing circuit is configured to select the first image data to identify visual features that are spatially distributed along a direction parallel to the first orientation direction, and
wherein processing circuit is configured to select the second image data to identify visual features that are spatially distributed along a direction parallel to the second orientation direction.

13. The imaging system according to claim 12,
wherein processing circuit is configured to select the first image data to identify linear features that extend along a linear direction parallel to the first orientation direction, and
wherein processing circuit is configured to select the first image data to identify linear features that extend along a linear direction parallel to the second orientation direction.

14. The imaging system according to claim 11,
wherein the processing circuit is configured to logically divide the field of view of the imaging system in a plurality of regions based on the type of visual features present in each region, and
wherein the processing circuit is configured to select the first image data and/or the second image data to determine image information for a region of the plurality of regions based on the type of visual features present in that region.

15. An imaging device comprising:
an image sensor comprising an array of sensor pixels
wherein the array of sensor pixels has a first lateral dimension in a first direction and second lateral dimension in a second direction orthogonal to the first direction, wherein the first lateral dimension is greater than the second lateral dimension; and
imaging optics configured to collect light and project the collected light onto the array of sensor pixels,
wherein the imaging optics is configured to project the collected light onto the array of sensor pixels,
wherein the imaging optics is configured to define a first effective focal length for the first direction and a second effective focal length for the second direction, wherein the first effective focal length is greater than the second effective focal length.

16. The imaging device according to claim 15,
wherein a ratio of the second effective focal length to the first effective focal length is equal to a ratio of the second lateral dimension in the second direction to the first lateral dimension in the first direction.

17. The imaging device according to claim 15,
wherein an aspect ratio defined as a ratio of the second lateral dimension in the second direction to the first lateral dimension in the first direction is in the range from 1:2 to 1:10.

18. The imaging device according to claim 15,
wherein the imaging optics is further configured to define a first angular field of view in the first direction and a second angular field of view in the second direction, and
wherein a ratio between a first angular extension of the first angular field of view and a second angular extension of the second angular field of view is in the range from 0.55 to 1.8.

19. The imaging device according to claim 18,
wherein the first angular field of view and the second angular field have a same angular extension.

20. The imaging device according to claim 15,
wherein at least one sensor pixel is configured to be sensitive for light in a first wavelength range;
wherein at least one other sensor pixel is configured to be sensitive for light in a second wavelength range, and
wherein the first wavelength range is different from the second wavelength range.
